(19) United States
(12) Patent Application Publication
(10) Pub. No.: US 2008/0042119 A1
(43) Pub. Date: Feb. 21, 2008

(54) Multi-layered chalcogenide and related devices having enhanced operational characteristics

(75) Inventors: Regino Sandoval, Rochester Hills, MI (US); Wolodymyr Czubatyj, Warren, MI (US); Tyler Lowrey, Rochester Hills, MI (US); Isamu Asano, Tokyo (JP)

Correspondence Address: ENERGY CONVERSION DEVICES, INC., 2956 WATERVIEW DRIVE, ROCHESTER HILLS, MI, 48309, US

(73) Assignee: Ovonyx, Inc.

(21) Appl. No.: 11/821,246

(22) Filed: Jun. 22, 2007

Related U.S. Application Data
(63) Continuation-in-part of application No. 11/451,913, filed on Jun. 13, 2006.
(63) Continuation-in-part of application No. 11/301,211, filed on Dec. 12, 2005.
(63) Continuation-in-part of application No. 11/200,466, filed on Aug. 9, 2005.

(51) Int. Cl. H01L 47/00

(52) U.S. Cl. 257/4; 257/E47.001; 257/E45.002

(57) ABSTRACT

A multi-layer chalcogenide, memory or switching device. The device includes an active region disposed between a first terminal and a second terminal. The active region includes a first layer and a second layer, where one of the layers is a heterogeneous layer that includes an operational component and a promoter component. The other layer may be a homogeneous or heterogeneous layer. In exemplary embodiments, the operational component is a chalcogenide or phase change material and the promoter component is an insulating or dielectric material. Inclusion of the promoter component provides beneficial performance characteristics such as a reduction in reset current or minimization of formation requirements.

### CROSS-REFERENCE TO RELATED APPLICATIONS

This application is a continuation in part of U.S. patent application Ser. No. 11/451,913 entitled “Multi-Layer Chalcogenide Devices” filed on Jun. 13, 2006, and a continuation in part of U.S. patent application Ser. No. 11/301,211 entitled “Chalcogenide Devices and Materials Having Reduced Germanium or Tellerium Content” filed on Dec. 12, 2005, and a continuation in part of U.S. patent application Ser. No. 11/200,466 entitled “Chalcogenide Devices Incorporating Chalcogenide Materials Having Reduced Germanium or Tellerium Content” filed on Aug. 9, 2005; the disclosures of which are hereby incorporated by reference herein.

### FIELD OF INVENTION

This invention pertains to chalcogenide materials having applications as electrical and optical memories and switches. More particularly, this invention relates to chalcogenide devices having an improved interface between a chalcogenide material and an electrical contact. Most particularly, this invention is concerned with a multi-layer material structure whose improved interface provides an improved operational characteristic, such as at least one of a decreased virgin resistance, decreased Rset, higher 10 year retention temperature, faster programming speed, better ohmic contact to resistive “heater” electrodes, increased range between set and reset resistances, reduced programming energy requirements, improved consistency of set and reset resistance values over a cycle life, and extended cycle life.

### BACKGROUND OF THE INVENTION

Chalcogenide materials are an emerging class of commercial electronic materials that exhibit switching, memory, logic, and processing functionality. The basic principles of chalcogenide materials were developed by S. R. Ovshinsky in the 1960's and much effort by him and others around the world since then have led to advancements of the underlying science and an expansion of the field of application of chalcogenide materials.

Early work in chalcogenide devices demonstrated electrical switching behavior in which switching from a resistive state to a conductive state was induced upon application of a voltage at or above the threshold voltage of the active chalcogenide material. This effect is the basis of the Ovonic Threshold Switch (OTS) and remains an important practical feature of chalcogenide materials. The OTS provides highly reproducible switching at ultrafast switching speeds for over 10¹³ cycles. Basic principles and operational features of the OTS are presented, for example, in U.S. Pat. Nos. 3,271,591; 5,543,737; 5,694,146; and 5,757,446; the disclosures of which are hereby incorporated by reference, as well as in several journal articles including “Reversible Electrical Switching Phenomena in Disordered Structures”, Physical Review Letters, vol. 21, p. 1450-1453 (1969) by S. R. Ovshinsky; “Amorphous Semiconductors for Switching, Memory, and Imaging Applications”, IEEE Transactions on Electron Devices, vol. ED-20, p. 91-105 (1973) by S. R. Ovshinsky and H. Fritzsche; the disclosures of which are hereby incorporated by reference.

Another important application of chalcogenide materials is in electrical and optical memory devices. One type of chalcogenide memory device utilizes the wide range of resistance values available for the material as the basis of memory operation. Each resistance value corresponds to a distinct structural state of the chalcogenide material and one or more of the states can be selected and used to define operational memory states. Chalcogenide materials exhibit a crystalline state or phase as well as an amorphous state or phase. Different structural states of a chalcogenide material differ with respect to the relative proportions of crystalline and amorphous phase in a given volume or region of chalcogenide material. The range of resistance values is generally bounded by a set state and a reset state of the chalcogenide material. The set state is a low resistance structural state whose electrical properties are primarily controlled by the crystalline portion of the chalcogenide material and the reset state is a high resistance structural state whose electrical properties are primarily controlled by the amorphous portion of the chalcogenide material.

Each memory state of a chalcogenide memory material corresponds to a distinct resistance value and each memory resistance value signifies unique informational content. Operationally, the chalcogenide material can be programmed into a particular memory state by providing an electric current pulse of appropriate amplitude and duration to transform the chalcogenide material into the structural state having the desired range of resistance. By controlling the amount of energy provided to a chalcogenide material, it is possible to control the relative proportions of crystalline and amorphous phase regions within a volume of the material and to thereby control the structural (and memory) state of the chalcogenide material to store information.

Each memory state can be programmed by providing the current pulse characteristic of the state and each state can be identified or read in a non-destructive fashion by measuring the resistance. Programming among the different states is fully reversible and the memory devices can be written over a very large number of programming cycles and read over a virtually unlimited number of cycles to provide robust and reliable operation. The variable resistance memory functionality of chalcogenide materials is currently being exploited in the OUM (Ovonic Universal (or Unified) Memory) devices that are beginning to appear on the market. Basic principles and operation of OUM type devices are presented, for example, in U.S. Pat. Nos. 6,859,390; 6,774,387; 6,687,153; and 6,314,014; the disclosures of which are incorporated by reference herein as well as in several journal articles including “Low Field Amorphous State Resistance and Threshold Voltage Drift in Chalcogenide Materials”, published in IEEE Transactions on Electron Devices, vol. 51, p. 714-719 (2004) by Pirovana et al.; and “Morphing Memory” published in IEEE Spectrum, vol. 167, p. 363-364 (2005) by Weiss.

The behavior (including switching, memory, and accumulation) and chemical compositions of chalcogenide materials have been described, for example, in the following U.S. Pat. Nos. 6,671,710; 6,714,954; 6,087,674; 5,166,758; 5,296,716; 5,536,947; 5,596,522; 5,825,046; 5,687,112; 5,912,839; and 3,530,441, the disclosures of which are hereby incorporated by reference. These references present proposed mechanisms that govern the behavior of the chalcogenide materials. The references also describe the structural transformations from the crystalline state to the amorphous state (and vice versa) via a series of partially crystalline states in which the relative proportions of crystalline and amorphous regions vary during the operation of electrical and optical chalcogenide devices.

Current commercial development of the chalcogenide materials and devices is also oriented toward the fabrication of arrays of devices. Chalcogenide materials offer the promise of high density memory, logic and neural arrays that can operate according to traditional binary data storage or according to a multilevel scheme. Chalcogenide arrays further offer the prospect of integrating, on a single chip, both memory and data processing capabilities, thereby enabling high speed, low cost, and highly functional operation.

In order to further expand the commercial prospects of chalcogenide phase change memories and switches, it is necessary to consider improvements in the chemical and physical properties of chalcogenide materials as well as refinements in the manufacturing processes. In most currently envisioned near-term memory applications, chalcogenide materials are operated in a binary mode where the memory states correspond to, or approximately correspond to, the set state and the reset state since these states provide the greatest contrast in resistance and thus facilitate discrimination of the state of the material during read out.

An outstanding problem that has been identified in the prior art concerns the variability of the set and/or reset resistance of chalcogenide memory devices in the first several cycles of operation of the as-fabricated device. In the typical fabrication process for chalcogenide memory devices, the chalcogenide material is deposited on a lower electrical contact in a kinetically-inhibited or otherwise structurally disordered state and an upper electrical contact is subsequently deposited on the chalcogenide material. The resistance of the device following fabrication, and before the application of an electrical current pulse, may be referred to as the virgin resistance (R_{Virgin}) of the device. Subsequent application of an electrical current pulse causes the material to achieve an initial set state having an initial set state resistance (R_{Set,0}). The initial set state can be reset to a first reset state by applying a higher amplitude electrical current pulse. The first reset state can be set by applying a set current pulse to produce another set state having a set state resistance R_{Set,1} and the process can be repeated over multiple set-reset cycles. For each set state achieved upon cycling, a resistance R_{Set,n} can be measured where R_{Set,n} corresponds to the resistance of the set state that is obtained after the device has been reset n times.

When the values of R_{Virgin} and R_{Set,n} are compared for different cycles (represented by different values of n), significant differences are commonly observed in the values of the virgin resistance and set resistance over the first several cycles. The most significant change normally occurs between R_{Virgin} and R_{Set,0}, with the deviations decreasing from R_{Set,0} to R_{Set,1} to R_{Set,2} etc. until the value of the set resistance stabilizes. A similar variability may also occur for the resistance of the reset state. For practical memory applications, variability in either the set resistance or reset resistance is undesirable because those resistances are commonly used as indicators for the memory states. Variability in the set resistance or reset resistance reduced the circuit margin for reliably and reproducibly establishing and detecting the memory states.

In order to eliminate the problem of variability in the prior art devices, it is necessary to undergo a formation process prior to utilization of chalcogenide memory devices in practical applications. The formation process involves post-fabrication electrical conditioning of the device and entails subjecting the device to a sufficient number of set-reset cycles to stabilize the resistances of the set state and/or reset state of the device so that the device is ready for its intended end use. An analogous need for formation or conditioning arises in the chalcogenide switching materials, where variability in the threshold voltage is commonly observed over the course of the first several switching events until a stable threshold voltage is attained. Because of the time and expense associated with the formation process, it is desirable to either simplify it (e.g. by reducing the number of cycling events required to achieve stable device performance) or eliminate it altogether.

In general terms, there are two primary factors that potentially contribute to the variability in the resistances and threshold voltages of chalcogenide memory and switching devices. First, the chemical composition and/or physical characteristics of the chalcogenide material may influence the structural state of the chalcogenide upon deposition and the extent to which it varies upon cycling through the set and reset states. Stable set resistances, reset resistances and threshold voltages may require stable and consistent structural configurations of the chalcogenide over multiple cycles of setting, resetting and/or switching. The extent to which the structure varies over multiple cycles may depend on the composition of the chalcogenide. The composition may influence the crystal structure of the crystalline phase that forms upon setting, the relative proportions of crystalline and amorphous phase regions present at a particular resistance value, the spatial arrangement of crystalline and amorphous phase regions, and the kinetic and thermodynamic energy barriers associated with structural rearrangements and changes in phase. Some or all of these factors may contribute to the consistency of the set resistance, reset resistance and/or threshold voltage of a chalcogenide device.

Amelioration of the variability of the set and reset resistances of chalcogenide devices through modifications of the chemical composition has been described in the co-pending parent application Ser. Nos. 11/451,913 ('913 application, filed on Jun. 13, 2006), 11/200,466 ('466 application, filed Aug. 9, 2005), and 11/301,211 ('211 application, filed Dec. 12, 2005), the disclosures of which are incorporated by reference herein. More specifically, the '913, '466, and '211 applications disclose a family of chalcogenide materials comprising Ge, Sb, and Te that contain a relatively low concentration of Ge and/or Te relative to standard prior art chalcogenide alloys such as Ge₂Sb₂Te₅. The new materials were shown to reduce or eliminate variability in the set resistance upon initial cycling from the virgin state and to require fewer or no cycles to complete formation.

A second factor that may contribute to variability in the resistances and/or threshold voltages of chalcogenide materials is the quality of the interface between the chalcogenide material and either or both of the upper and lower electrical contacts in a chalcogenide device. Since the measured resistance of a chalcogenide device includes the resistance of the interfacial region of the contacts, variability in the characteristics of the interface may lead to variability in the resistance values.

Accordingly, there is a need to improve the quality of the interface and its effect on the reproducibility and consistency of the set resistance, reset resistance, programming current, and/or threshold voltage of chalcogenide devices, as well as extend the practical life of the devices.

### SUMMARY OF THE INVENTION

The instant invention provides exemplary embodiments of chalcogenide memory and switching devices that include an active region that includes a memory or switching material extending between two electrical terminals. In one embodiment, the active region includes two or more layers and at least one of the layers includes a chalcogenide material. In another embodiment, at least one of the layers of the active region is a heterogeneous layer that includes a chalcogenide material and a promoter material distributed as a component within. The promoter component is distributed as one or more discrete regions within the heterogeneous layer and provides performance benefits such as reduced interface resistance between the heterogeneous layer and an electrical contact, less stringent conditioning requirements for device operation, lower reset current, greater contrast between the reset resistance and set resistance of the active region, and enhanced set speed of the active region.

An electronic device in accordance with an exemplary embodiment is provided. The electronic device includes a first terminal, a second terminal, and an active region of memory material in electrical communication with the first and second terminals. The active region of memory material includes a first layer and a second layer. In one embodiment, the first layer is is a heterogeneous layer that includes an operational component and a promoter component. The operational component may be a chalcogenide material, a memory material or a switching material. The promoter component is distributed as one or more discrete regions within the heterogeneous layer and is generally surrounded by the operational component. The promoter component is generally an insulating or resistive material and may be an oxide, nitride, chalcogenide, or non-chalcogenide material having a chemical composition distinguishable from the chemical composition of the chalcogenide material. In one embodiment, the second layer is a chalcogenide material. In another embodiment, the second layer is a chalcogenide material that includes a promoter component.

An electronic device in accordance with another exemplary embodiment is provided. The electronic device includes a first terminal, a second terminal, and an active region extending from the first terminal to the second terminal. The active region includes a first layer in electrical communication with the first terminal, a second layer in electrical communication with the second terminal, and a third layer disposed between the first and second layers. The third layer is in electrical communication with the first and second layers. One or more of the first, second, and third layers may be a chalcogenide material, a memory material or a switching material. One or more of the first, second, and third layers may be a heterogeneous layer that includes an operational component and a promoter component

### BRIEF DESCRIPTION OF THE DRAWINGS

FIG. 1 is a schematic depiction of the resistance of a chalcogenide material as a function of energy or current;

FIG. 2 is a schematic depiction of a symmetric embodiment of a current vs. voltage relationship of a chalcogenide material;

FIG. 3-5 illustrate embodiments of dual-layer devices having various combinations of homogenous and/or heterogeneous material layers in accordance with the instant invention;

FIG. 6 is a resistance vs. current relationship of a dual-layer device that includes a 200 Å thick lower layer of Ge₁₈Sb₃₇Te₄₅ and a 550 Å thick upper layer of Ge₂Sb₂Te₅ in the active region of the dual-layer device;

FIG. 7 is a current vs. voltage relationship of the dual-layer device of FIG. 6;

FIG. 8 illustrates the reset and set resistances of the dual-layer device of FIG. 6 over multiple cycles of operation;

FIG. 9 depicts a resistance vs. current relationship of a dual-layer device that includes a 200 Å thick lower layer of Ge₁₈Sb₃₇Te₄₅ containing 8% SiO₂ and a 550 Å thick upper layer of Ge₂Sb₂Te₅ in the active region of the dual-layer device;

FIG. 10 shows a current vs. voltage relationship of the dual-layer device of FIG. 9;

FIG. 11 illustrates the reset and set resistances of the dual-layer device of FIG. 9 over multiple cycles of operation;

FIG. 12 depicts a resistance vs. current relationship of a dual-layer device that includes a 200 Å thick lower layer of Ge₁₈Sb₃₇Te₄₅ and a 550 Å thick upper layer of Ge₂Sb₂Te₅ containing 8% SiO₂ in the active region of the dual-layer device;

FIG. 13 shows a current vs. voltage relationship of the dual-layer device of FIG. 12;

FIG. 14 illustrates the reset and set resistances of the dual-layer device of FIG. 12 over multiple cycles of operation;

FIG. 15 depicts a resistance vs. current relationship of a dual-layer device that includes a 200 Å thick lower layer of Ge₁₈Sb₃₇Te₄₅ and a 550 Å thick upper layer of Ge₂Sb₂Te₅ containing 10% SiO₂ in the active region of the dual-layer device;

FIG. 16 shows a current vs. voltage relationship of the dual-layer device of FIG. 15;

FIG. 17 illustrates the reset and set resistances of the dual-layer device of FIG. 15 over multiple cycles of operation;

FIG. 18 illustrates a comparison of resistance vs. current relationships for various configurations of dual-layer devices presented herein.

### DETAILED DESCRIPTION OF EXEMPLARY EMBODIMENTS

Although this invention will be described in terms of certain preferred embodiments, other embodiments that are apparent to those of ordinary skill in the art, including embodiments that do not provide all of the benefits and features set forth herein, are also within the scope of this invention. Accordingly, the scope of the invention is defined only by reference to the appended claims.

One of the challenges in the field of chalcogenide devices has been the identification of an effective combination of an active chalcogenide material and a surrounding device structure that optimizes device performance. Among the desirable performance characteristics of chalcogenide memory devices are a high reset resistance, low set resistance, fast set speed, long cycle life, low reset current, stable and reproducible operation, and little or no need for formation following fabrication. Ideally, it is desirable to simultaneously achieve all of the preferred operational characteristics with a single chalcogenide material within a manufacturable device structure. In practice, however, it is found that optimization of some of the desirable operational characteristics occurs at the expense of other desirable operational characteristics. Ge₂Sb₂Te₅, for example, is a widely used chalcogenide material. Ge₂Sb₂Te₅ offers the advantages of a high reset resistance and low reset current, but suffers from the drawbacks of a high virgin resistance, slow set speed, high set resistance, and relatively demanding formation requirements.

While not wishing to be bound by theory, a factor that is believed to contribute in part to the detrimental operational characteristics of Ge₂Sb₂Te₅ is the low quality interface that forms between Ge₂Sb₂Te₅ and the contacts of the device structure that provide electrical signals to Ge₂Sb₂Te₅. The contacts may also be referred to herein as electrical contacts, terminals or electrodes. It has been experimentally determined that it is difficult to form a good contact between Ge₂Sb₂Te₅ and many of the higher resistance materials commonly used as contacts. The inability to form a good contact is believed to contribute to the high virgin and set resistances of devices based on Ge₂Sb₂Te₅ and to the failure of such devices over prolonged cycling.

Under one theory, the interface of Ge₂Sb₂Te₅ with electrical contacts is compromised through the formation of germanium oxide phases. The formation of germanium oxide phases is believed to occur either during device fabrication or during device operation upon repeated set-reset cycles. The characteristics of the germanium oxide phases may evolve over time or upon cycling and this evolution contributes to the need to condition the devices prior to practical operation by end users. Furthermore, like oxides generally, the germanium oxide phases are resistive and have the effect of measurably increasing the set resistance of the device above that dictated by the structural state of the chalcogenide material.

A desire to curtail the deleterious effects of germanium oxide phases motivated the inventions described in the co-pending parent application Ser. Nos. 11/451,913 ('913 application); 11/200,466 ('466 application); and 11/301,211 ('211 application), the disclosures of which are incorporated by reference herein. The '913, '466, and '211 applications are directed at chalcogenide materials having a relatively low Ge concentration. It is expected that a reduction of the Ge concentration in the chalcogenide composition will inhibit the formation of germanium oxide phases and improve the performance of chalcogenide devices. As described in the '913, '466, and '211 applications, the low Ge concentration chalcogenide alloys showed low virgin and set resistances and a greatly reduced need for formation.

This suggests that an improved interface forms between the low Ge concentration chalcogenide alloys and common electrode materials. The improved interface may be due to an inhibition in the formation of resistive germanium oxide phases and/or formation of a low resistance contact between the low Ge concentration chalcogenide alloys and common electrode materials. The low Ge concentration chalcogenide alloys also showed improved set speeds. A full comparative assessment of the properties of devices that include the low Ge concentration chalcogenide alloys relative to devices that include Ge₂Sb₂Te₅ indicates, however, that the low Ge concentration chalcogenide alloys lead to lower reset resistances and higher reset currents.

Based on the results available for the low Ge concentration chalcogenide devices and Ge₂Sb₂Te₅ devices, it would be desirable to combine the beneficial features of each in a single device system. The instant invention is directed in part toward this goal. This invention provides chalcogenide devices having an improved interface between the chalcogenide material and one or more electrical contacts of a chalcogenide memory or switching device having two or more terminals, while achieving a high reset resistance and/or low reset current.

Among the objectives of the instant invention is the achievement of chalcogenide devices having a low resistance at the interface of the active chalcogenide material and an electrical contact. The resistance at the interface between a chalcogenide material and an electrical contact may be referred to herein as the interface resistance or a contact resistance. The measured resistance of a chalcogenide device includes the resistances of the top and bottom contacts, the interface resistance at the top and bottom contacts and the resistance of the chalcogenide material located between the top and bottom contacts. The chalcogenide material located between the top and bottom contacts, and away from the interface, may be referred to herein as the bulk chalcogenide material. The region of the device located between the top and bottom contacts may be referred to herein as the active region of the device and the material or materials located in the active region may also be referred to herein as the active material or materials of the device. If the active region includes a chalcogenide material, it may also be referred to herein as the active chalcogenide region.

It is generally desirable for the measured resistance of a chalcogenide device to be controlled primarily by the resistance of the bulk chalcogenide material. This objective is desirable because differences in the resistance of the chalcogenide material that occur upon a change of phase (e.g. changes in the relative proportions of amorphous and crystalline regions within a volume of chalcogenide material) may be used to distinguish and define different memory states. In order for a memory device to be effective, the resistances of the different memory states must be readily distinguishable to permit accurate and unambiguous reading of the information stored in the device.

If the interface resistance at either or both of the top and bottom contacts is high due to the presence of a persistent resistive phase such as a germanium oxide, the ability to reliably distinguish different memory states may be compromised. Consider, for example, a limiting case in which the resistance at an interface is infinite. In such a case, the measured resistance of the device is infinite regardless of the resistance of the bulk chalcogenide material. As a result, the state of the chalcogenide material has no effect on the measured resistance and changes in resistance that accompany changes in the phase of the chalcogenide material become undetectable. In this scenario, the different memory states represented by different structural states of the chalcogenide material become indistinguishable and unresolvable on the basis of a measurement of the device resistance.

As the interface resistance decreases, however, the contribution of the bulk chalcogenide material to the measured resistance increases and changes in the resistance of the chalcogenide material that accompany changes in its structural state provide a more meaningful contribution to the measured resistance. The ability to detect and resolve the different memory states is accordingly improved. In the limit of no interface resistance, the measured resistance of the device is controlled by the resistance of the bulk chalcogenide material and any change in the resistance of the bulk chalcogenide material becomes more readily detectable. The problem of interface resistance is most pronounced for the set state of the device since the chalcogenide resistance is lowest for the set state, which means that the interface resistance exerts a proportionately greater influence on the measured resistance when the device is in the set state.

Strategies for controlling the interface resistance can in principle involve modifications to the material used for electrical contacts or to the composition of the chalcogenide memory or switching material. Since the materials used for electrical contacts are frequently constrained by process requirements, it is desirable to identify chalcogenide materials that form high quality, low resistance contacts to the best performing, most convenient, and widely used electrical contact materials. This is one strategy that is pursued in the instant invention.

In addition to low interface resistance at either or both of the upper and lower contacts, it is further desirable to have the memory states of a memory device span a wide range of resistance values. In the case of binary memory devices, a wide range of resistance values provides greater resolution of the memory states (typically the set state and reset state) and simplifies discrimination of the two states. In multistate memory devices, a wide range of resistance values provides for a greater number of memory states for a given resolution between states. When achieving the objective of an improved interface resistance, it is therefore preferable to do so while maintaining a large difference in the resistances of the set state and reset state. As described in further detail hereinbelow, embodiments of the instant invention provide chalcogenide devices that exhibit high quality, low resistance interfaces. Embodiments further include chalcogenide devices having a low resistance interface in combination with a high resistance reset state.

Embodiments of the instant invention include chalcogenide devices having an active region that includes two or more layers, where each layer has a different chemical composition and at least one of the layers comprises a chalcogenide material. As used herein, the active region refers to the region disposed between two or more contacts of an electronic device such as a memory or switching device. In one embodiment, the electronic device is a chalcogenide device where the active chalcogenide region is disposed between an upper contact and a lower contact in a two-terminal device configuration.

In one embodiment, the active region includes two chalcogenide layers having distinguishable chemical compositions. In this embodiment, one of the layers is designed to provide a high quality and/or low resistance interface with either the upper or lower contact, while the other layer is designed to have at least one performance characteristic that is superior to the same characteristic of the other layer. In one embodiment, one of the layers is Ge₂Sb₂Te₅ or a Ge-rich alloy and the other layer is a Ge-lean chalcogenide alloy such as, for example, those described in the '466 and '211 applications. In another embodiment, one of the layers is Ge₂Sb₂Te₅ or a Ge-rich alloy and the other layer is Sb or an Sb-rich alloy.

Other embodiments of the instant invention include an active region that contains three layers (chalcogenide and/or Sb) with an upper layer forming an interface with the upper contact, a lower layer forming an interface with the lower contact and a third layer disposed between the upper and lower chalcogenide layers. In this embodiment, the upper and lower chalcogenide interface layers are designed to provide a high quality and/or low resistance interface with the upper and lower contacts, respectively, while the remaining intermediate layer is designed to possess a performance characteristic that surpasses the same characteristic in one or both of the upper and lower chalcogenide layers. The upper and lower chalcogenide interface layers may have the same or different composition and the intermediate chalcogenide layer has a composition that differs from at least one of the upper and lower chalcogenide interface layers. In one embodiment, the upper and lower chalcogenide interface layers include a Ge-lean or Sb-rich chalcogenide alloy such as those described in the '913, '466, and '211 applications and the intermediate chalcogenide layer is Ge₂Sb₂Te₅.

By combining two or more layers having different chalcogenide compositions in the active region of the device, the instant invention achieves improved performance characteristics by benefiting from the desirable characteristics of different compositions in a single device structure. The beneficial reset resistance of Ge₂Sb₂Te₅ and low virgin resistance of a Ge-lean chalcogenide composition, for example, may be achieved in a single device structure. Additionally, as discussed more fully hereinbelow, by further combining a promoter material within at least one of the layers, the phase change device performance (such as reduced reset programming current) can be improved while simultaneously improving the quality of the interface between a chalcogenide material, memory material or switching material and one or more of the electrical contacts.

Before describing the illustrative embodiments, it is helpful to review the basic principles of operation of chalcogenide materials. As described hereinabove, an important feature of the chalcogenide materials during the operation of chalcogenide memory devices and device arrays is their ability to undergo a phase transformation between or among two or more structural states. (The importance of phase transformations in memory applications has prompted some people to refer to chalcogenide materials as phase change materials and they may be referred to herein as such.) The chalcogenide materials have structural states that include a crystalline state, one or more partially-crystalline states and an amorphous state.

The crystalline state may be a single crystalline state or a polycrystalline state. As used herein, a partially-crystalline state refers to a structural state of a volume of chalcogenide material that includes an amorphous portion and a crystalline portion. Generally, a plurality of partially-crystalline states exists for the phase-change material that may be distinguished on the basis of the relative proportion of the amorphous and crystalline portions. Fractional crystallinity is one way to characterize the structural states of a chalcogenide phase-change material. The fractional crystallinity of the crystalline state is 100%, the fractional crystallinity of the amorphous state is 0%, and the partially-crystalline states have fractional crystallinities that vary continuously between 0% (the amorphous limit) and 100% (the crystalline limit). Phase-change chalcogenide materials are thus able to transform among a plurality of structural states that vary inclusively between fractional crystallinities of 0% and 100%.

Transformations among the structural states of a chalcogenide material are induced by providing energy to the chalcogenide material. Energy in various forms can influence the fractional crystallinity of a chalcogenide material and induce structural transformations. Suitable forms of energy include electrical energy, thermal energy, optical energy or other forms of energy (e.g. particle-beam energy) that induce electrical, thermal or optical effects in a chalcogenide material. Combinations of different forms of energy may also induce structural transformations. Continuous and reversible variability of the fractional crystallinity is achievable by controlling the energy environment of a chalcogenide material. A crystalline state can be transformed to a partially-crystalline or an amorphous state, a partially-crystalline state can be transformed to a different partially-crystalline state as well as to either a crystalline or amorphous state, and an amorphous state can be transformed to a partially-crystalline or crystalline state through proper control of the energy environment of a chalcogenide material. Some considerations associated with the use of electrical energy to induce structural transformations are presented in the following discussion.

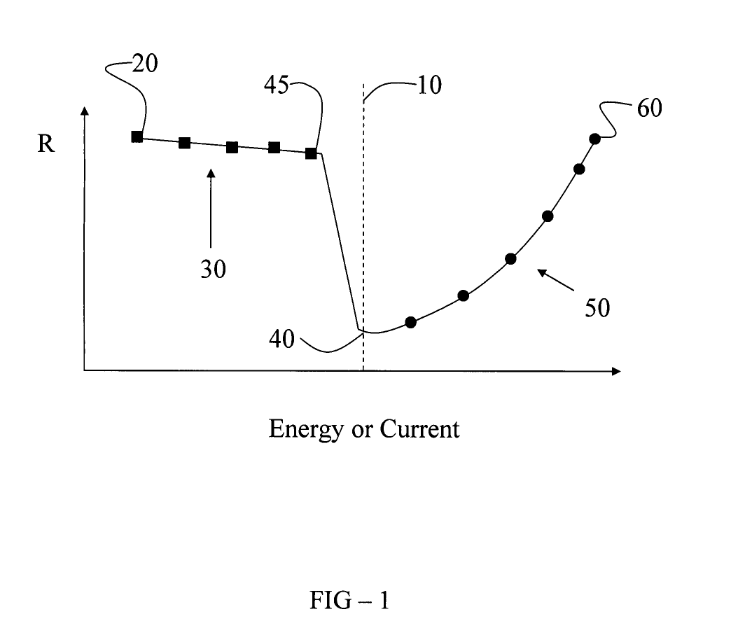

The use of electrical energy to induce structural transformations typically relies on the application of electrical (current or voltage) pulses to a chalcogenide material. By controlling the magnitude and/or duration of electrical pulses applied to a chalcogenide material, it is possible to continuously vary the fractional crystallinity. The influence of electrical energy on the structure of a chalcogenide material is frequently depicted in terms of the variation of the low field electrical resistance of a chalcogenide material with the amount of electrical energy provided or the magnitude of the current or voltage pulse applied to a chalcogenide material. A representative depiction of the low field electrical resistance (R) of a chalcogenide material as a function of electrical energy or current pulse magnitude (Energy/Current) is presented in FIG. 1 herein. FIG. 1 shows the variation of the low field electrical resistance of a chalcogenide material resulting from electrical energy or current pulses of various magnitude and may generally be referred to as a resistance verses current plot or R-I plot.

The resistance plot includes two characteristic response regimes of a chalcogenide material to electrical energy. The regimes are approximately demarcated with the vertical dashed line 10 shown in FIG. 1. The regime to the left of the line 10 may be referred to as the accumulating regime of the chalcogenide material. The accumulation regime is distinguished by a nearly constant or gradually varying electrical resistance with increasing electrical energy that culminates in an abrupt decrease in resistance at the point where a percolation path is reached Percolation refers to the establishment of a conducting path in an otherwise non-conducting medium, e.g. steel ball bearings in a sand. Electrical conduction in such a medium is very small if the percentage of ball bearings is small. At some percentage, the ball bearings will touch and form a conducting path after which a further increase in the percentage of ball bearings does not change the electrical conduction significantly. The accumulation regime thus extends, in the direction of increasing energy, from the leftmost point 20 of the resistance plot, through a plateau region (generally depicted by 30) corresponding to the range of points over which the resulting resistance variation is small or gradual up to the set point or state 40 that follows an abrupt decrease in electrical resistance. The plateau 30 may be horizontal or sloping.

The left side of the resistance plot is referred to as the accumulating regime because the structural state of the chalcogenide material continuously evolves as energy is applied, with the fractional crystallinity of the structural state correlating with the total accumulation of applied energy. The leftmost point 20 corresponds to the structural state in the accumulating regime having the lowest fractional crystallinity. This state may be fully amorphous or may contain some residual crystalline content. As energy is added, the fractional crystallinity increases, and the chalcogenide material transforms in the direction of increasing applied energy among a plurality of partially-crystalline states along the plateau 30. Selected accumulation states (structural states in the accumulation region) are marked with squares in FIG. 1

Upon accumulation of a threshold amount of applied energy, where the percolation path is established, the fractional crystallinity of the chalcogenide material increases sufficiently to effect a setting transformation that is characterized by a dramatic decrease in electrical resistance and stabilization of the set state 40. Structural transformations in the accumulating regime are unidirectional in the sense that they progress in the direction of increasing applied energy within the plateau region 30 and are reversible only by amorphizing or resetting chalcogenide material.

The behavior illustrated in FIG. 1 is reproducible over many cycles of setting and resetting a device containing a chalcogenide material by applying the requisite energy or current. Once the reset state is obtained, lower amplitude current pulses can again be applied and the accumulation response of the chalcogenide material can be retraced. It is thus possible to cycle between the set and reset states over multiple cycles, a necessary feature for high memory cycle life.

While not wishing to be bound by theory, the instant inventors believe that the addition of energy to a chalcogenide material in the accumulating regime leads to an increase in fractional crystallinity through the nucleation of new crystalline domains or growth of existing crystalline domains or a combination thereof. It is believed that the electrical resistance varies only gradually along the plateau 30 despite the increase in fractional crystallinity because the crystalline domains form or grow in relative isolation of each other so as to prevent the formation of a contiguous crystalline network that spans the chalcogenide material between the two device electrodes. This type of crystallization may be referred to as sub-percolation crystallization. The setting transformation coincides with a percolation threshold in which a contiguous, interconnected crystalline network forms within the chalcogenide material between the two device electrodes.

Such a network may form, for example, when crystalline domains increase sufficiently in size to impinge upon neighboring domains. Since the crystalline phase of chalcogenide materials is less resistive than the amorphous phase, the percolation threshold corresponds to the formation of a contiguous low resistance conductive pathway through the chalcogenide material. As a result, the percolation threshold is marked by a dramatic decrease in the resistance of the chalcogenide material. The leftmost point of the accumulation regime may be an amorphous state or a partially-crystalline state lacking a contiguous crystalline network. Sub-percolation crystallization commences with an initial amorphous or partially-crystalline state and progresses through a plurality of partially-crystalline states having increasingly higher fractional crystallinities until the percolation threshold is reached and the setting transformation occurs.

The regime to the right of the line 10 of FIG. 1 may be referred to as the direct overwrite regime or direct overwrite region. The direct overwrite regime extends from the set state 40 through a plurality of intermediate states (generally depicted by 50) to a reset point or state 60. The various points in the direct overwrite regime may be referred to as direct overwrite states of the chalcogenide material. Selected direct overwrite states are marked with circles in FIG. 1. Structural transformations in the direct overwrite regime may be induced by applying an electric current or energy pulse to a chalcogenide material, as indicated in FIG. 1.

In the direct overwrite regime, the resistance of the chalcogenide material varies with the magnitude of the applied electric pulse. The resistance of a particular state in the direct overwrite regime is characteristic of the structural state of the chalcogenide material, and the structural state of a chalcogenide material is dictated by the magnitude of the current pulse applied in the direct overwrite region. The fractional crystallinity of the chalcogenide material decreases as the magnitude of the current pulse increases.

The fractional crystallinity is highest for direct overwrite states at or near the set point 40 and progressively decreases as the reset state 60 is approached. The chalcogenide material transforms from a structural state possessing a contiguous crystalline network at the set state 40 to a structural state that is amorphous or substantially amorphous or partially-crystalline without a contiguous crystalline network at the reset state 60. The application of current pulses having increasing magnitude has the effect of converting portions of the crystalline network into an amorphous phase and ultimately leads to a disruption or interruption of contiguous high-conductivity crystalline pathways in the chalcogenide material. As a result, the resistance of the chalcogenide material increases as the magnitude of an applied current pulse increases in the direct overwrite region.

In contrast to the accumulating region, structural transformations that occur in the direct overwrite region are reversible and bi-directional, this giving this region its name. As indicated hereinabove, each state in the direct overwrite region may be identified by its resistance and a current pulse magnitude, where application of that current pulse magnitude induces changes in fractional crystallinity that produce the particular resistance value of the state.

Application of a subsequent current pulse may increase or decrease the fractional crystallinity relative to the fractional crystallinity of the initial state of the chalcogenide material. If the subsequent current pulse has a higher magnitude than the pulse used to establish the initial state, the fractional crystallinity of the chalcogenide material decreases and the structural state is transformed from the initial state in the direction of the higher resistance reset state along the direct overwrite resistance curve. Similarly, if the subsequent current pulse has a lower magnitude than the pulse used to establish the initial state, the fractional crystallinity of the chalcogenide material increases and the structural state is transformed from the initial state in the direction of the lower resistance set state along the direct overwrite resistance curve.

In OUM (Ovonic Unified (or Universal) Memory) applications, the direct overwrite states of the chalcogenide material are used to define discrete levels of a memory device. Most commonly, the memory devices are binary memory devices that utilize two of the direct overwrite states as memory states, where a distinct information value (e.g. “0” or “1”) is associated with each state. Each memory state thus corresponds to a distinct structural state of the chalcogenide material and readout or identification of the state can be accomplished by measuring the resistance of the material (or device) since each structural state is characterized by a distinct resistance value as exemplified, for example, by the direct overwrite states in FIG. 1. The operation of transforming a chalcogenide material to the structural state associated with a particular memory state may be referred to herein as programming the chalcogenide material, writing to the chalcogenide material or storing information in the chalcogenide material.

To facilitate readout and to minimize readout error, as described hereinabove, it is desirable to select the memory states of a binary memory device so that the contrast in resistance of the two states is large. Typically the set state (or a state near the set state) and the reset state (or a state near the reset state) are selected as memory states in a binary memory application. The resistance contrast depends on details such as the chemical composition of the chalcogenide, the thickness of the chalcogenide material in the device and the geometry of the device.

For a layer of phase-change material having the composition Ge₂₂Sb₂₂Te₅₆, a thickness of approximately 600 Angstroms (Å), and pore diameter of below approximately 0.1 micrometers (μm) in a typical two-terminal device structure, for example, the resistance of the reset state is approximately 100-1000 kilo ohms (kΩ) and the resistance of the set state is under approximately 10 kΩ. Phase-change materials in general show resistances in the range of approximately 100-1000 kΩ in the reset state and resistance of approximately 0.5-50 kΩ in the set state.

In the preferred phase-change materials, the resistance of the reset state is at least a factor of two greater than the resistance of the set state. In addition to binary (single bit per device) memory applications, chalcogenide materials may be utilized as non-binary or multiple bit per device memory devices by selecting three or more states from among the direct overwrite states and associating an information value with each state, where each memory state corresponds to a distinct structural state of the chalcogenide and is characterized by a distinct resistance value.

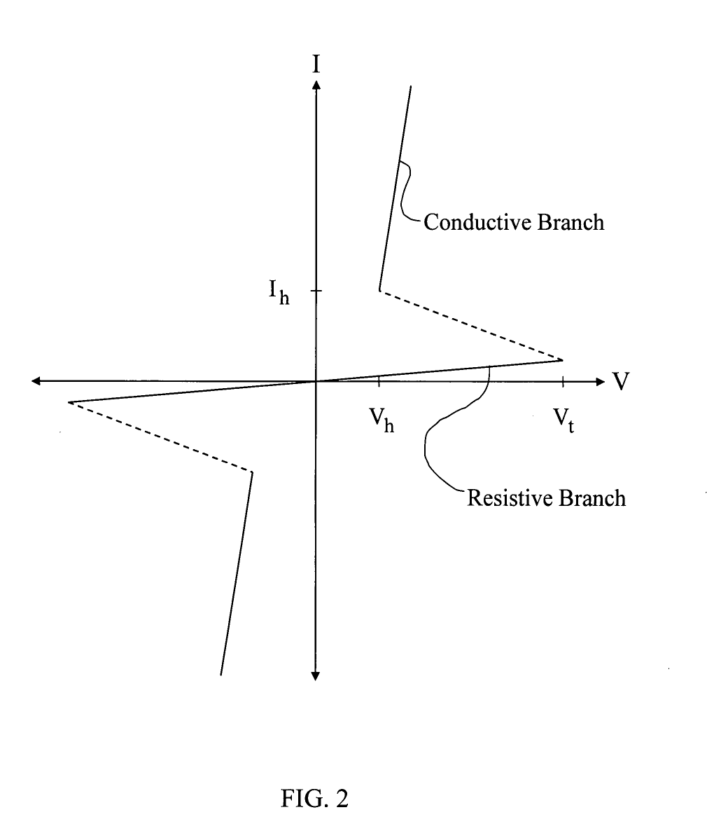

In addition to memory materials, the instant invention further extends to switching materials. Representative electrical switching characteristics of chalcogenide materials are schematically illustrated in FIG. 2, which shows the I-V (current-voltage) characteristics of a chalcogenide material. The I-V characteristics depicted in FIG. 2 may be conveniently described by considering a simple two-terminal device configuration in which two spacedly disposed electrodes are in contact with a chalcogenide material and the current (I) corresponds to the current passing between the two electrodes. The I-V curve shows the current passing through a chalcogenide material as a function of the voltage applied across the device, which includes the chalcogenide film and the two electrodes. The I-V characteristics of the material are generally symmetric with respect to the polarity of the applied voltage. For convenience, we consider the first quadrant of the I-V plot of FIG. 2 (the portion in which current and voltage are both positive) in the brief discussion of chalcogenide switching behavior that follows. An analogous description applies to the third quadrant of the I-V plot.

The I-V curve of a chalcogenide material in accordance with the instant invention includes a resistive branch and a conductive branch. The branches are labeled in FIG. 2. The resistive branch corresponds to a branch in which the current passing through the material increases only slightly upon increasing the voltage applied across the device. This branch exhibits a small slope in the I-V plot and appears as a more nearly horizontal line in the first and third quadrants of FIG. 2. The conductive branch corresponds to a branch in which the current passing through the material increases significantly upon increasing the voltage applied across the device. This branch exhibits a large slope in the I-V plot and appears as a more nearly vertical line in the first and third quadrants. The particular slopes of the resistive and conductive branches shown in FIG. 2 are illustrative and not intended to be limiting, the actual slopes will depend on the chemical composition, thickness etc. of the chalcogenide material as well as on parameters such as the resistance, load, capacitance etc. of surrounding circuit elements. Regardless of the actual slopes, the conductive branch necessarily exhibits a larger (steeper) slope than the resistive branch. When device conditions are such that the chalcogenide material is described by a point on the resistive branch of the I-V curve, the chalcogenide material or device may be said to be in a resistive state. When device conditions are such that the chalcogenide material is described by a point on the conductive branch of the I-V curve, the chalcogenide material or device may be said to be in a conductive state.

The capacity of a chalcogenide material in accordance with the instant invention to carry a current can be described by reference to FIG. 2. We initially consider a two-terminal device configuration in which no voltage difference is present between the terminals. When no voltage is applied across the chalcogenide material, the material is in a resistive state and no current flows. This condition corresponds to the origin of the I-V plot shown in FIG. 2. The chalcogenide remains in a resistive state as the applied voltage is increased, up to a threshold voltage (labeled Vₜ in the first quadrant of FIG. 2). The slope of the I-V curve for applied voltages between 0 and Vₜ is small in magnitude and indicates that the chalcogenide material has a high electrical resistance, a circumstance reflected in the terminology “resistive branch” used to describe this portion of the I-V curve. The high resistance implies low electrical conductivity and as a result, the current flowing through the material increases only weakly as the applied voltage is increased.

When the applied voltage equals or exceeds the threshold voltage, the chalcogenide material transforms or switches from the resistive branch to the conductive branch of the I-V curve. The switching event occurs almost instantaneously and is depicted by the dashed line in FIG. 2. Upon switching, the device voltage decreases significantly and the device current becomes much more sensitive to changes in the device voltage. The chalcogenide material remains in the conductive branch as long as a minimum current, labeled Iₕ in FIG. 2, is maintained. We refer to Iₕ as the holding current and the associated voltage Vₕ as the holding voltage of the device. If the device conditions are changed so that the current becomes less than Iₕ, the material normally returns to the resistive branch of the I-V plot and requires re-application of a threshold voltage to resume operation on the conductive branch. If the current is only momentarily (e.g. a time less than the recovery time of the chalcogenide material) reduced below Iₕ, the conductive state of the chalcogenide may be recovered upon restoring the current to or above Iₕ.

Analogous switching behavior occurs in the third quadrant of the I-V plot shown in FIG. 2. Provided one is cognizant of the negative polarity of the I-V curve in the third quadrant, the switching behavior and current characteristics in the third quadrant is analogous to that described hereinabove for the first quadrant. For example, applied voltages having a magnitude greater than the magnitude of the negative threshold voltage in the third quadrant induce a transformation or switching from the resistive branch to the conductive branch.

Many chalcogenide memory materials also undergo a switching process similar to the one described in FIG. 2. Because chalcogenide memory materials undergo a phase change, however, their switching is not reversible simply by removing the applied voltage. Instead, the operational characteristics of chalcogenide memory materials are dominated by the phase change characteristics described in FIG. 1 hereinabove. The most effective switching materials resist a change of phase and generally remain in a single phase. Many chalcogenide switching materials, for example, remain in an amorphous phase during the transformation from a resistive state to a conductive state.

A wide range of chalcogenide compositions has been investigated in an effort to optimize the performance characteristics of chalcogenide memory or switching devices. Chalcogenide materials generally include a chalcogen element and one or more chemical or structural modifying elements. The chalcogen element (e.g. Te, Se, S) is selected from column VI of the periodic table and the modifying elements can be selected from column III (e.g. Ga, Al, In), column IV (e.g. Si, Ge, Sn), or column V (e.g. P, As, Sb) of the periodic table. The role of modifying elements includes providing points of branching or crosslinking between chains comprising the chalcogen element.

Column IV modifiers can function as tetracoordinate modifiers that include two coordinate positions within a chalcogenide chain and two coordination positions that permit branching or crosslinking away from the chalcogenide chain. Column III and V modifiers can function as tricoordinate modifiers that include two coordinate positions within a chalcogenide chain and one coordinate position that permits branching or crosslinking away from the chalcogenide chain. Embodiments of the instant devices include ternary, quaternary and higher chalcogenide alloys. Selected specific embodiments of the chalcogenide composition are described in further detail below.

Chalcogenide alloys that include the elements Ge, Sb, and/or Te are among the most promising materials for electrical and optical devices. As indicated hereinabove, the alloy Ge₂Sb₂Te₅ is widely used in chalcogenide electrical memory devices. Ge₂Sb₂Te₅ is among the alloys located on the Ge₂Te₃—Sb₂Te₃ tieline of a ternary Ge—Te—Sb phase diagram. Other alloys of the tieline are also widely used and within the scope of the instant invention. In addition, off-tieline alloys such as those described in the '913, '466, and '211 applications are also within the scope of the instant invention.

Embodiments of the instant invention provide electronic devices that include chalcogenide materials for improved electrode interface properties whose composition includes Ge and Sb. In one embodiment, the atomic concentration of Ge is between 11% and 21%. In another embodiment, the atomic concentration of Ge is between 13% and 20%. In another embodiment, the atomic concentration of Ge is between 15% and 18%. In one embodiment, the atomic concentration of Sb is between 22% and 65%. In another embodiment, the atomic concentration of Sb is between 28% and 43%. In another embodiment, the atomic concentration of Sb is between 32% and 35%. In each of the foregoing embodiments, the composition ranges indicated for each of the elements is inclusive of the endpoint compositions.

The instant invention further includes memory and electronic devices that include chalcogenide materials for improved electrode interface properties having Ge and Sb in the concentration ranges described above as well as Te. In one embodiment, the atomic concentration of Te is between 28% and 55%. In another embodiment, the atomic concentration of Te is between 43% and 55%. In another embodiment, the atomic concentration of Te is between 48% and 51%. In each of the foregoing embodiments, the composition ranges indicated for each of the elements is inclusive of the endpoint compositions.

Other embodiments of the instant invention include chalcogenide devices that include materials for improved electrode interface properties having Ge and Sb where the atomic concentration of Ge is less than or equal to 20% and the atomic concentration of Sb is greater than or equal to 30%. In one embodiment, the atomic concentration of Ge is less than or equal to 16% and the atomic concentration of Sb is greater than or equal to 40%. In another embodiment, the atomic concentration of Ge is less than or equal to 12% and the atomic concentration of Sb is greater than or equal to 50%.

In other embodiments, the instant devices include chalcogenide material having the foregoing atomic concentrations of Sb and an atomic concentration of Ge between 11% and 19%, more preferably between 13% and 18% and most preferably between 15% and 17%. In still other embodiments, the chalcogenide material includes Ge and Sb in the foregoing atomic concentrations and further includes Te. In one embodiment, the atomic concentration of Te is less than or equal to 50% and more preferably between 20% and 50%. In another embodiment, the atomic concentration of Te is less than or equal to 40% and more preferably between 30% and 40%. In another embodiment, the atomic concentration of Te is less than or equal to 30%.

In other embodiments, the devices include a chalcogenide alloy for improved electrode interface properties having a Ge concentration in the range from 11%-22%, an Sb concentration in the range from 22%-65%, and a Te concentration in the range from 28%-55%. In another embodiment, the alloy is a material having a Ge concentration in the range from 13%-20%, an Sb concentration in the range from 28%-43%, and a Te concentration in the range from 43%-55%. In one embodiment, the alloy is a material having a Ge concentration in the range from 15%-18%, an Sb concentration in the range from 32%-35%, and a Te concentration in the range from 48%-51%.

A representative list of chalcogenide materials, intended to be illustrative rather than limiting, suitable for inclusion in one or more layers of the active region of the instant devices is provided in Table 1 below.

TABLE 1
Chalcogenide Material
Ge_{45.5}Sb_{15.5}Te_{38.9}
Ge₄₂Sb₄₃Te₁₅
Ge_{42.0}Sb_{38.5}Te_{19.5}
Ge_{37.8}Sb_{17.8}Te_{44.4}
Ge_{36.1}Sb_{36.1}Te_{27.8}
Ge₃₁Sb₅₄Te₁₅
Ge_{31.0}Sb_{49.5}Te_{19.5}
Ge_{30.5}Sb_{30.5}Te_{38.9}
Ge_{25.2}Sb_{40.7}Te_{35.1}
Ge₂₅Sb₅₀Te₂₅
Ge₂₅Sb₄₅Te₃₀
Ge₂₅Sb₄₀Te₃₅
Ge_{25.0}Sb_{35.5}Te_{39.5}
Ge₂₅Sb₂₅Te₅₀
Ge_{22.2}Sb_{22.2}Te_{55.5}
Ge₂₀Sb₆₅Te₁₅
Ge_{20.0}Sb_{60.5}Te_{19.5}
Ge₂₀Sb₃₀Te₅₀
Ge_{20.0}Sb_{25.5}Te_{54.5}
Ge_{17.8}Sb_{37.8}Te_{44.4}
Ge_{17.8}Sb_{33.3}Te_{48.9}
Ge_{15.6}Sb_{41.1}Te_{43.4}
Ge_{15.5}Sb_{45.5}Te_{38.9}
Ge_{13.5}Sb₅₃Te_{33.5}
Ge_{13.3}Sb_{48.8}Te_{37.8}
Ge_{11.1}Sb_{61.1}Te_{27.8}
Ge_{11.1}Sb_{56.6}Te_{32.3}
Ge_{0.09}Sb_{0.69}Te_{0.22}
Ge_{8.9}Sb_{64.4}Te_{26.7}
Ge₇Sb₇₇Te₁₇
Ge_{6.7}Sb_{72.2}Te_{21.2}

It is contemplated that exemplary embodiments of the present invention include two or more chalcogenide, memory, and/or switching materials that may be combined in the active region of an electronic device. For instance and in one embodiment, the materials may be interspersed or co-mingled within the active region of the electronic device. In an alternative embodiment, the materials may be deposited sequentially as one or more layers, where each layer corresponds to a homogeneous composition. As described more fully hereinbelow, the instant invention further contemplates electronic devices with active regions that include one or more heterogeneous layers where a heterogeneous layer includes an operational component and a promoter component.

In another alternative embodiment, the layers are arranged vertically between an upper contact and a lower contact with each layer extending across a lateral diameter of the active region. In yet another alternative embodiment, a memory layer having a first chemical composition is in physical contact with one terminal of the device and a memory layer having a second chemical composition is in physical contact with a second terminal of the device. And in yet another alternative exemplary embodiment, phase-change memory materials other than chalcogenide memory materials may be used in the active region of the memory devices.

As discussed above, memory or switching materials that include Ge-lean chalcogenide compositions combined with Ge₂Sb₂Te₅ provide high quality interface characteristics with electrical terminals commonly used in electronic devices. As discussed in the '913 application, Ge₂Sb₂Te₅ memory material may not provide a desirably low virgin resistance when used as a single-layer memory material in the memory device.

Exemplary embodiments of the present invention are directed to modifying the active material of an electronic device to improve performance characteristics of the device. In one exemplary embodiment, a promoter material is utilized with a chalcogenide, memory, or switching material to improve performance. The promoter material may, for example, enhance the quality of the interface between the chalcogenide, memory, or switching material and one or more electrical contacts or terminals of the electronic device. In one embodiment, the promoter material operates to reduce the interface resistance between the active material and an electrical contact of the device. In another embodiment, the promoter material operates to inhibit the formation or resistive oxides at the interface between the chalcogenide, memory or switching material and an electrical contact of the device. Illustrative beneficial performance characteristics that may result from inclusion of a promoter material with a chalcogenide, memory or switching material in the active region of the instant devices include one or more of reducing virgin resistance, reducing set resistance, increasing reset resistance, increasing the contrast between the set resistance and the reset resistance, lowering reset current, improving the consistency of set and reset resistance values over repeated cycles, minimizing the number of conditioning or formation cycles needed to stabilize device operation (including performance parameters such as set resistance, reset resistance, and threshold voltage), and extending cycle life compared to an electronic device without the promoter material.

In one exemplary embodiment, the promoter material is an element or compound, including a combination thereof, combined with a chalcogenide, memory or switching material to improve one or more performance characteristics of the device. For example and in one embodiment, one of the layers of a dual-layer memory material includes a promoter material, such as SiO₂ or SiOₓ to improve the performance of a device that includes a dual layer chalcogenide, memory or switching material in the active region. The promoter material may, for example, lower the resistance at the interface between the active material and an electrical contact of the device. In an alternative exemplary embodiment, both layers of a dual-layer active region material include an amount of SiO₂ or SiOₓ to improve the performance characteristics of the device. In addition to SiO₂, promoter materials according to the instant invention include other oxides (e.g. metal or non-metal oxides), nitrides (e.g. SiNₓ, TiNₓ), carbides (e.g. SiC), other insulating or resistive materials, non-chalcogenide materials or the like.

The promoter material may be combined with a chalcogenide, memory or switching material in the active region of an electronic device through various chemical and physical processing techniques. A general objective is to form an active region, or layer within an active region, that includes a combination of a promoter material and a chalcogenide, memory or switching material. In a preferred embodiment, the chalcogenide, memory or switching material is a phase-change material. In one embodiment, the combination of the promoter material with a chalcogenide, memory or switching material is a compositionally heterogeneous region or layer in which the promoter material is present in the form of a dispersed component. In one embodiment, a heterogeneous layer or region is formed in a co-sputtering process in which the promoter material and chalcogenide, memory or switching material are sputtered simultaneously or partially simultaneously. In another embodiment, a heterogeneous layer or region is formed in a chemical or physical vapor deposition process by introducing precursors of the promoter material and a memory or switching material during the deposition and simultaneously forming the promoter material and chalcogenide, memory or switching material.

It is contemplated that in an exemplary embodiment, the promoter material is selected and combined with a chalcogenide, memory or switching material in a manner so that the promoter material may not necessarily contact one of the terminals after fabricating the device. For example, the promoter material may aid in configuring the conductive filament when formed in a chalcogenide, switching or memory material for greater or more uniform conductivity along the filament. Additionally, the promoter material may also aid in reducing the formation of germanium oxides as discussed hereinabove, thereby promoting the quality of the interface between the material in the active region and a terminal. The promoter material may also aid in configuring the filament by facilitating the electron ionization or avalanche process associated with the creation of the filament by altering the energy required for liberation of electrons from lone pair or valence states of chalcogen elements.

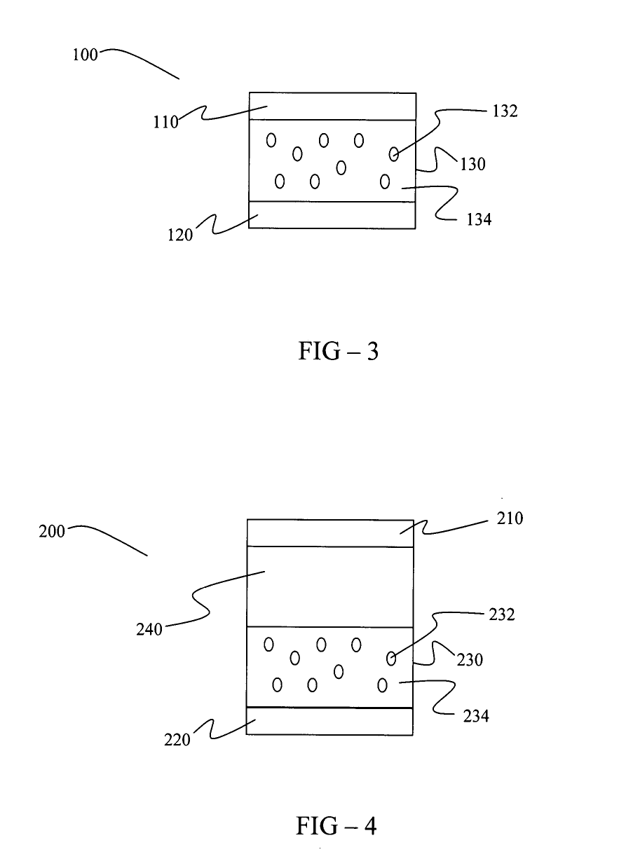

Schematic depictions of illustrative embodiments of the instant invention are shown in FIGS. 3-5. FIG. 3 shows electronic device 100 that includes upper terminal 110, lower terminal 120, and active region 130. Active region 130 is a heterogeneous layer that includes operational component 134 and promoter component 132. The operational component may also be referred to as an operational material and the promoter component may also be referred to as a promoter material. Operational component 134 is a chalcogenide, memory, switching or phase-change material. Operational component 134 is responsive to application of a voltage or current between upper terminal 110 and lower terminal 120. Operational component 134 may, for example, transform from one structural state to another in response to an applied voltage or current. In one embodiment, the structural transformation is from a more crystalline state to a less crystalline state. In another embodiment, the structural transformation is from a less amorphous state to a more amorphous state. In yet another embodiment, the structural transformation is from one crystalline state to another crystalline state. Operational component 134 may also switch from a resistive state to a conductive state or vice versa upon application of a current or voltage. Promoter 132 is dispersed within operational component 134. Promoter 132 is generally dispersed as a plurality of discrete regions within operational component 134. The discrete regions may be arranged in an ordered or disordered fashion within operational component 134 and the different discrete regions may be of the same or similar size and shape or may differ in size or shape. As indicated hereinabove, promoter materials according to the instant invention include SiO₂, SiOₓ, other oxides (e.g. metal or non-metal oxides), nitrides (e.g. SiNₓ, TiNₓ), carbides (e.g. SiC), other insulating or resistive materials, non-chalcogenide materials or the like.

Promoter component 132 may be incorporated in various proportions within heterogeneous layer 130. In one embodiment, the volume fraction of promoter component 132 is between 1% and 12%. In a preferred embodiment, the volume fraction of promoter component 132 is between 3% and 10%. In a more preferred embodiment, the volume fraction of promoter component 132 is between 5% and 8%.

FIG. 4 shows electronic device 200 that includes upper terminal 210, lower terminal 220, and an active region that includes heterogeneous layer 230 and homogeneous layer 240. Heterogeneous layer 230 includes operational component 234 and promoter component 232. Operational component 234 is a chalcogenide, memory, switching or phase-change material. Operational component 234 is responsive to application of a voltage or current between upper terminal 210 and lower terminal 220. Promoter 232 is dispersed within operational component 234. Promoter 232 is generally dispersed as a plurality of discrete regions within operational component 234. Homogeneous layer 240 may include a chalcogenide, memory or switching material and is disposed over heterogeneous layer 230. In one embodiment, homogeneous layer 240 is responsive to application of a current or voltage between upper terminal 210 and lower terminal 220. The invention further contemplates dual layer embodiments in which the heterogeneous layer is disposed over a homogeneous layer.

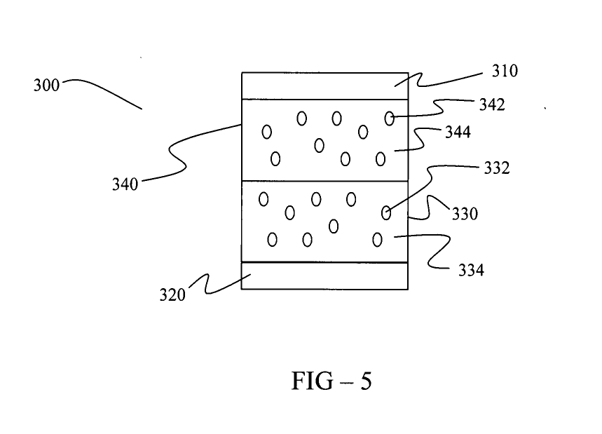

FIG. 5 shows electronic device 300 that includes upper terminal 310, lower terminal 320, and an active region that includes heterogeneous layer 330 and heterogeneous layer 340. Heterogeneous layer 330 includes operational component 334 and promoter component 332. Operational component 334 is a chalcogenide, memory, switching or phase-change material. Operational component 334 is responsive to application of a voltage or current between upper terminal 310 and lower terminal 320. Promoter 332 is dispersed within operational component 334. Promoter 332 is generally dispersed as a plurality of discrete regions within operational component 334. Heterogeneous layer 340 includes operational component 344 and promoter component 342. Operational component 344 is a chalcogenide, memory, switching or phase-change material. Operational component 344 is responsive to application of a voltage or current between upper terminal 310 and lower terminal 320. Promoter 342 is dispersed within operational component 344. Promoter 342 is generally dispersed as a plurality of discrete regions within operational component 344 may include a chalcogenide, memory or switching material.

Other embodiments of the instant invention include electronic devices with active regions having three or more layers disposed between a pair of terminals. The three or more layers may include one or more homogeneous layers and/or one or more heterogeneous layers. The homogeneous layers may include a chalcogenide, memory, or switching material and the heterogeneous layers may include an operational component and a promoter component, where the operational component may be a chalcogenide, memory or switching material and the promoter component is as described hereinabove. The homogeneous and heterogeneous layers may be arranged in any order relative to each other.

Illustrative examples of devices according to the instant invention are now described:

### EXAMPLE 1

In this example, the fabrication of electronic devices in accordance with the instant invention is described. The devices include two or more homogeneous and/or heterogeneous layers in the active region. The device structure described in this example is a two-terminal device design having two or more layers disposed in an active region having a plug geometry, where the active region is in electrical contact with top and bottom electrodes. The different homogeneous and heterogeneous layers are deposited in a sequential fashion. The depositions occurred on a base Si wafer that included a thick SiO₂ surface oxide layer disposed over a pre-fabricated nitridized refractory metal or metal alloy. A plug of nitridized refractory metal or metal alloy for a bottom electrode having a diameter of approximately 600 Å was formed in the insulating layer. As described in further detail below, one or more homogeneous or heterogeneous layers were next deposited on the plug and its surrounding oxide insulator to a total thickness of ˜750 Å at 200° C. using a pulsed DC co-sputtering process. Targets of Ge₂Sb₂Te₅, Ge, and Sb were used in the deposition of chalcogenide materials as either homogeneous layers or operational components of heterogeneous layers. A target of SiO₂ promoter material was also included in the sputtering process. By controlling the power, ion energetics, time of exposure and utilization of the different targets in the sputtering process, chalcogenide films of different composition were prepared and heterogeneous layers having various proportions of promoter material were prepared. The sputtering occurred in an Ar environment.

One or more homogeneous and/or heterogeneous layers of Ge₂Sb₂Te₅ and Ge₁₈Sb₃₇Te₄₅ were included in the active region of the illustrative devices described hereinbelow. SiO₂ is used as the promoter material in these illustrative examples. The dual chalcogenide layers coated the plug and extended laterally over the surrounding insulating layer. A top electrode was then deposited in situ and included a 400 Å carbon layer deposited on top of the active region and one or more conductive layers deposited on top of the carbon layer. The conductive layers typically included a 1000 Å molybdenum nitride layer. Appropriate lithography and patterning was performed on each device design to permit electrical testing of the devices and the devices were subjected to annealing at 300° C. for 30 minutes.

Illustrative dual layer devices having the following combinations of homogeneous and/or heterogeneous chalcogenide layers in accordance with the instant invention were fabricated:

TABLE 2

| | Layer in Contact with | Layer in Contact with |
|---|---|---|
| Device Label | Lower Electrode | Upper Electrode |
| o5785 | Ge₁₈Sb₃₇Te₄₅ (200 Å) | Ge₂Sb₂Te₅ (550 Å) |
| o5787 | Ge₁₈Sb₃₇Te₄₅ (200 Å) | Ge₂Sb₂Te₅ (550 Å) |
| | includes 8% SiO₂ | |
| o5789 | Ge₁₈Sb₃₇Te₄₅ (200 Å) | Ge₂Sb₂Te₅ (550 Å) |
| | | includes 8% SiO₂ |
| o5791 | Ge₁₈Sb₃₇Te₄₅ (200 Å) | Ge₂Sb₂Te₅ (550 Å) |
| | | includes 10% SiO₂ |

Each of the devices listed in the above table is identified by a device label. The combination of chalcogenide layers included in the active region of each device is listed along with the thickness of each layer. The layers are listed according to whether they are in physical contact with the lower electrode or upper electrode in the as-processed device. Each of the illustrative devices includes a layer of Ge₁₈Sb₃₇Te₄₅ having a thickness of 200 Å in contact with the lower electrode and a layer of Ge₂Sb₂Te₅ having a thickness of 550 Å in contact with the upper electrode. The alloy Ge₁₈Sb₃₇Te₄₅ was selected as a representative embodiment of a low Ge content alloy intended to promote the quality of the interface formed with a device electrode as described in the '913, '211, and '466 applications. Ge₂Sb₂Te₅ was selected because of its desirable high reset resistance. As described in the '913 application, a dual layer Ge₁₈Sb₃₇Te₄₅—Ge₂Sb₂Te₅ device has several performance advantages.

Dual layer device o5785 is a control device that includes a homogeneous layer of Ge₁₈Sb₃₇Te₄₅ in combination with a homogeneous layer of Ge₂Sb₂Te₅. No promoter material was included in the active region of device o5785. Dual layer devices o5787, o5789, and o5791 include one homogeneous layer and one heterogeneous layer that incorporates SiO₂ as a promoter component. Device o5787 includes a heterogeneous layer in contact with the lower electrode and a homogeneous layer in contact with the upper electrode. The heterogeneous layer includes operational component Ge₁₈Sb₃₇Te₄₅ and promoter component SiO₂, where the volume fraction of the promoter component is 8%. The homogenous layer is a layer of Ge₂Sb₂Te₅. Device o5789 includes a homogeneous layer in contact with the lower electrode and a heterogeneous layer in contact with the upper electrode. The homogenous layer is a layer of Ge₁₈Sb₃₇Te₄₅. The heterogeneous layer includes operational component Ge₂Sb₂Te₅ and promoter component SiO₂, where the volume fraction of the promoter component is 8%. Device o5791 includes a homogeneous layer in contact with the lower electrode and a heterogeneous layer in contact with the upper electrode. The homogenous layer is a layer of Ge₁₈Sb₃₇Te₄₅. The heterogeneous layer includes operational component Ge₂Sb₂Te₅ and promoter component SiO₂, where the volume fraction of the promoter component is 10%.

Separate base wafers were used for each type of device indicated in Table 2. The base wafers for each type of device each were identical. In the fabrication of devices on each base wafer, a plurality of devices having the particular combination of heterogeneous and/or homogeneous layers indicated in Table 2 were prepared and tested. Illustrative performance characteristics for each type of device are described in the Examples presented hereinbelow. The performance characteristics reflect representative performance results for the plurality of devices of each type formed on each base wafer. Performance characteristics for each type of device were consistent across the plurality of devices formed on each of the base wafers. The operational characteristics of the devices are qualitatively similar to the behavior depicted in FIG. 1. Specific performance advantages associated with the devices that include the instant promoter material are discussed in the Examples that follow.

### EXAMPLE 2

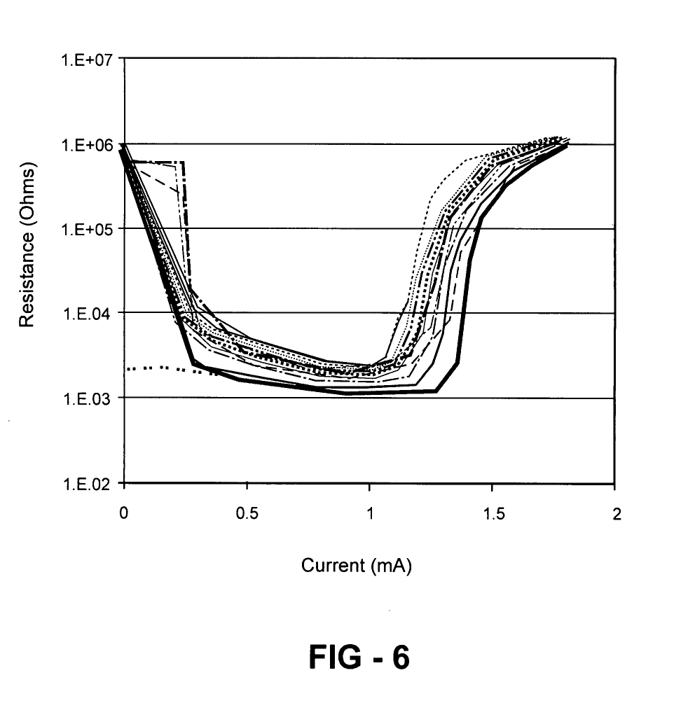

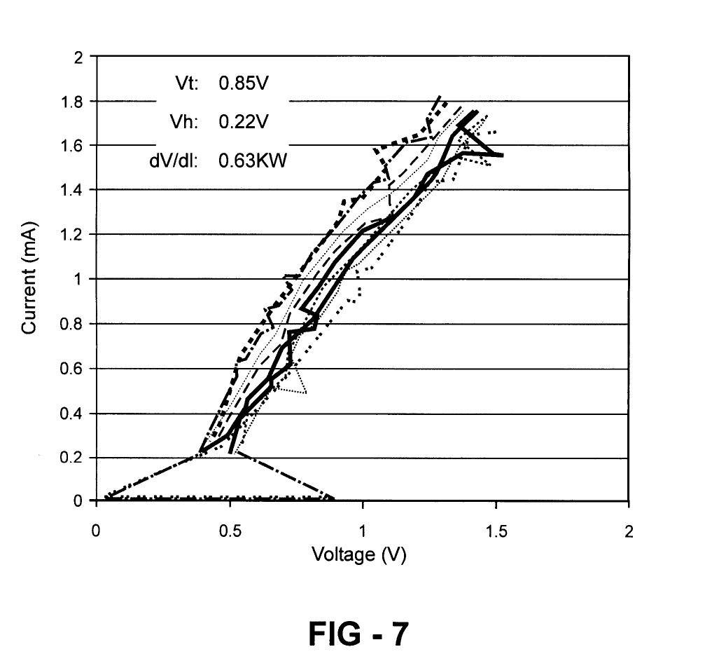

This example presents selected experimental results from the electrical testing of control device o5785. The I-V (Current-Voltage) and R-I (Resistance-Current) characteristics of the control sample are presented. The experimental results were obtained by applying voltage pulses with a pulse duration of 300 ns and various pulse amplitudes to the device. The voltage pulses were applied between the top and bottom electrodes of the device and current through the device was measured while the voltage pulse was applied. When the voltage pulse concluded, the resistance of the device was measured as well. A DC bias voltage of approximately 0.1 to 0.4 volts (V) was maintained during the read measurement. A series of voltage pulses was applied to a series-fixed resistor (R_{load}) in series with the electronic device under test and data was obtained for each pulse. The series of voltage pulses applied began at approximately 0.2 V and was increased in small increments up to a maximum voltage value that was sufficient to reset the device. Resistance and current of the device under test were obtained as a function of pulse amplitude from the data and summarized in the form of the R-I and I-V plots shown in FIGS. 6 and 7.

R-I and I-V characteristics of the devices were measured over multiple cycles of operation. The different cycles correspond to cycles of setting and resetting the device, beginning with the as-fabricated or virgin state of the device and continuing until the response characteristic of the device substantially stabilized. The number of cycles required to stabilize device performance is a measure of the extent of formation or conditioning required to prepare the device for its ultimate intended operation. It is desirable to minimize the number of cycles needed to form the device and it is expected that a higher quality interface between the memory material, such as a chalcogenide material, and one or both electrodes will reduce the number of cycles needed for formation, as discussed in the '913 application.

FIG. 6 depicts the R-I characteristics for electronic device o5785 over several cycles of operation. The first cycle of operation is depicted as a series of data points denoted with diamond symbols that begins with the virgin state of the as-fabricated device and extends until the device reached its first reset state. The data point for the device in its virgin state is located at zero current and a resistance of approximately 2 kΩ (the virgin resistance) in FIG. 6. As the amplitude of the voltage pulses was increased, the current passing through the device increased. The device resistance remained generally near the virgin resistance until a current above 1.0 mA passed through the device. At this point, the resistance of the device increased substantially and the device was transformed to its reset state. The second cycle of operation began with the device in the reset state obtained upon conclusion of the first cycle of operation. A second series of voltage pulses of increasing amplitude was applied and the resistance and current of the device were measured to produce a second trace of the R-I plot. The resistance of the initial state of the second cycle of operation was close to 1 MΩ. During the second cycle of operation, the device set to a low resistance state as the current approached 0.5 mA and reset again as the current exceeded 1 mA. The cycling process was continued and data traces for several cycles are shown in FIG. 6.

The R-I data for the control device indicate that the device required little or no formation. Little variation in the set state resistance and reset state resistance of the device were observed after the second cycle of operation. The R-I data for the control device indicate that it had a reset current of 1.5 mA.

The I-V characteristics of the control device are shown in FIG. 7. I-V traces over several cycles of operation are shown. The I-V trace for the first cycle of operation began with the virgin state and is depicted by the monotonically increasing diamond symbols extending from the origin of the plot and continuing to a voltage of about 1.4 V. No switching was observed for the first cycle of operation. Subsequent cycles of operation demonstrated switching, as signified by the nearly constant and low current passing through the device as the voltage was increased initially and the nearly discontinuous increase in current observed when the voltage reached the threshold voltage. The I-V characteristics of the control device showed little variation after the second or third cycle of operation. The I-V data indicated that the threshold voltage of the control device was 0.8 V-0.9 V and that the resistance in the conductive state was slightly above 600 Ω.

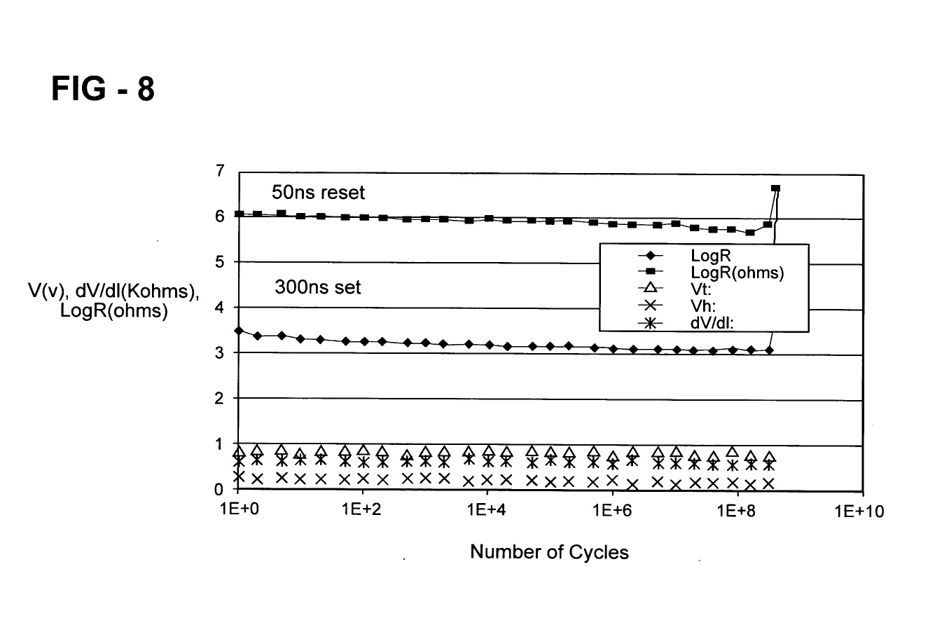

FIG. 8 shows the variation in several performance characteristics of the control device over a large number of operating cycles to investigate the durability and reliability of the device. Each operating cycle included a 300 ns set pulse and a 50 ns reset pulse. For each cycle, the set resistance, reset resistance, threshold voltage, holding voltage, and resistance in the conductive branch (dynamic state resistance) of the I-V curve were measured. The results are summarized in FIG. 8. The upper two traces show the variation of reset resistance and set resistance upon cycling. The reset resistance remained stable at approximately 1 MΩ for over 10⁸ operating cycles, at which point the device failed. The set resistance remained stable at a value of well below 10 kΩ over the same number of cycles. The lower three traces of FIG. 8, in order of increasing voltage, show the variation in holding voltage, conductive branch (dynamic state) resistance, and threshold voltage of the device. All three performance characteristics exhibited stable values until the device failed.

### EXAMPLE 3

This example presents selected experimental results from the electrical testing of device o5787. Device o5787 is an embodiment in accordance with the instant invention that includes a dual layer structure having a heterogeneous layer and a homogeneous layer. The layer in contact with the lower electrode is a 200 Å thick heterogeneous layer that includes Ge₁₈Sb₃₇Te₄₅ as the operational component and 8% SiO₂ as a promoter component. The layer in contact with the upper electrode is a 550 Å thick homogeneous layer of Ge₂Sb₂Te₅. The I-V (Current-Voltage), R-I (Resistance-Current) and cycle life characteristics of device o5787 over multiple cycles were obtained as described in EXAMPLE 2 hereinabove.

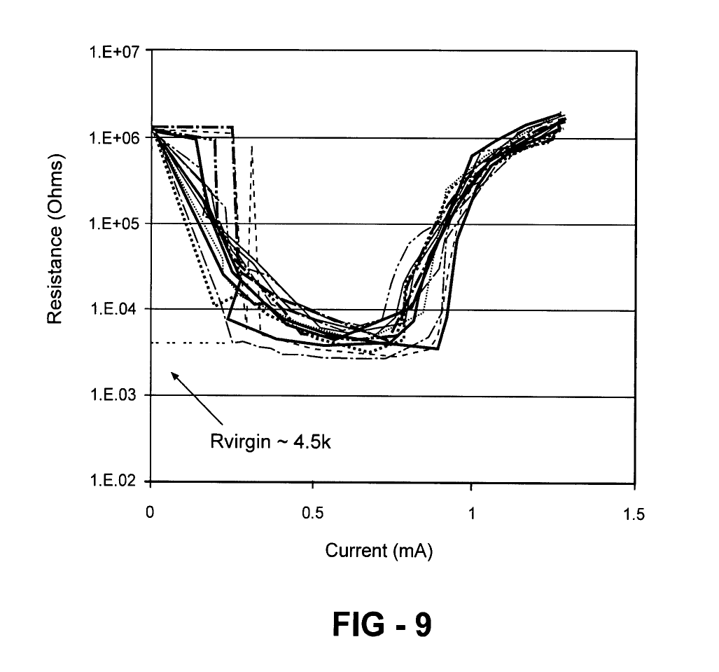

FIG. 9 depicts the R-I characteristics for electronic device o5787 over several cycles of operation. The first cycle of operation is depicted as a series of data points denoted with diamond symbols that begins with the virgin state of the as-fabricated device and extends until the device reached its first reset state. The data point for the device in its virgin state is located at zero current and a resistance of approximately 4.5 kΩ in FIG. 9. As the amplitude of the voltage pulses was increased, the current passing through the device increased. The device resistance remained generally near the virgin resistance until a current of approximately 0.8 mA passed through the device. At this point, the resistance of the device increased substantially and the device was transformed to its reset state. The second cycle of operation began with the device in the reset state obtained upon conclusion of the first cycle of operation. A second series of voltage pulses of increasing amplitude was applied and the resistance and current of the device were measured to produce a second trace of the R-I plot. The resistance of the initial state of the second cycle of operation was close to 1 MΩ. During the second cycle of operation, the device set to a low resistance state at a current of approximately 0.3 mA and reset again as the current approached 1 mA. The cycling process was continued and data traces for several cycles are shown in FIG. 9.

The R-I data for device o5787 indicate that the device required little or no formation. Little variation in the set state resistance and reset state resistance of the device were observed after the second cycle of operation. Inclusion of a promoter component in a layer of the active region thus had no significant deleterious effect on the advantageous formation properties observed for the control device in EXAMPLE 2. The R-I data for device o5787 also indicate that the device had a reset current of approximately 1.0 mA, a current that is significantly less than the reset current of the control device. The results thus indicate that inclusion of a promoter component within a layer of a dual layer device provides the beneficial effect of lowering the reset current of the device. A lower set current was also observed, while a large contrast between the reset resistance and set resistance was maintained upon inclusion of the promoter component.

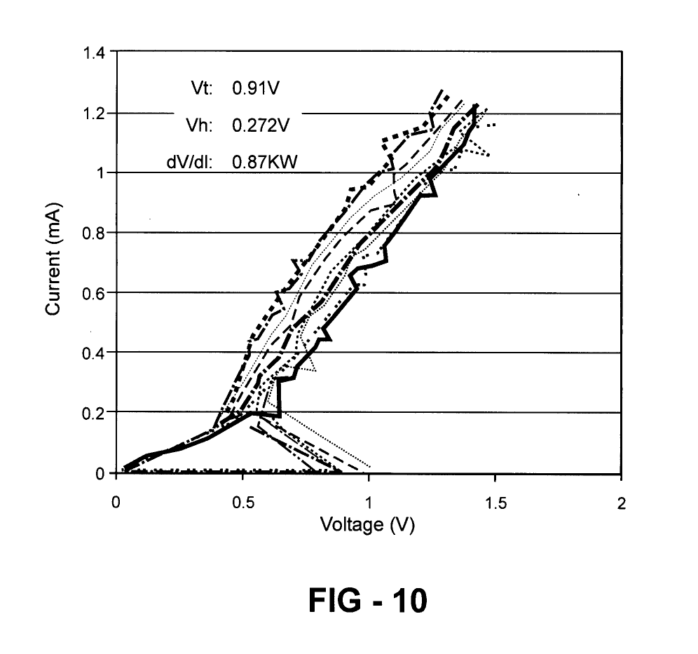

The I-V characteristics of the device o5787 are shown in FIG. 10. I-V traces over several cycles of operation are shown. The I-V trace for the first cycle of operation began with the virgin state and is depicted by the monotonically increasing diamond symbols extending from the origin of the plot and continuing to a voltage of about 1.4 V. No switching was observed for the first cycle of operation. Subsequent cycles of operation demonstrated switching. The I-V characteristics of device o5787 showed little variation after the second or third cycle of operation. The I-V data indicated that the threshold voltage of device o5787 was about 0.9 V and that the resistance in the conductive state was about 850Ω. The I-V characteristics of device o5787 were similar to those observed for the control device.

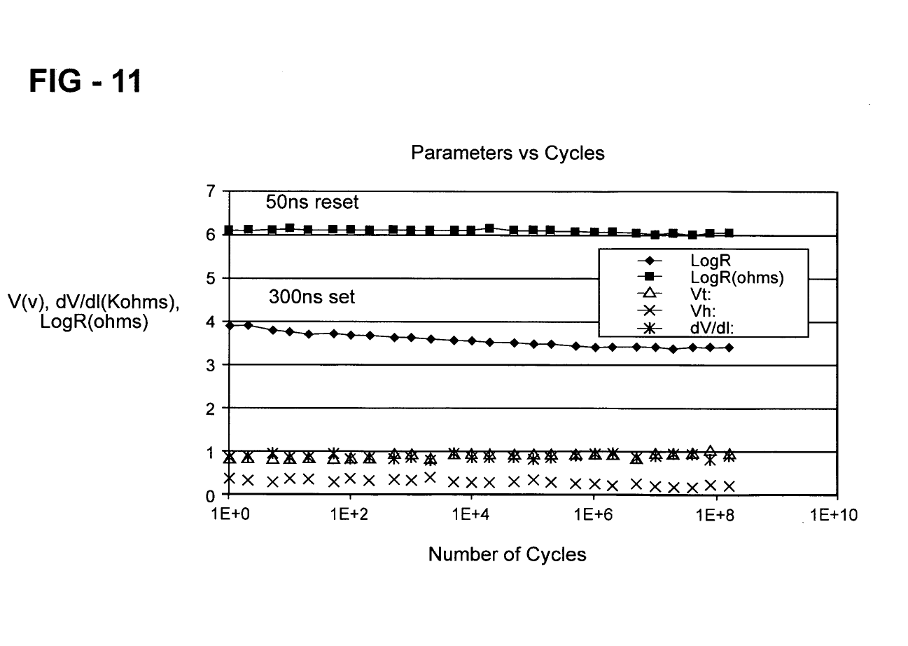

FIG. 11 shows the variation in several performance characteristics of device o5787 over multiple operating cycles. Each operating cycle included a 300 ns set pulse and a 50 ns reset pulse. For each cycle, the set resistance, reset resistance, threshold voltage, holding voltage, and resistance in the conductive branch (dynamic state resistance) of the I-V curve were measured. The results are summarized in FIG. 11. The upper two traces show the variation of reset resistance and set resistance upon cycling. The reset resistance remained stable at approximately 1 MΩ for over 10⁸ operating cycles, at which point the experiment was terminated and no failure of the device had occurred. The set resistance remained stable at a value of below 10 kΩ over the same number of cycles. The lower three traces of FIG. 11 show the variation in holding voltage, conductive branch (dynamic state) resistance, and threshold voltage of the device. All three performance characteristics exhibited stable values for the duration of the experiment. The cycle life tests indicate that inclusion of a promoter material within a layer of the active region of a dual layer device does not have a detrimental effect on durability of the device. The lifetime of device o5787 is at least as good as the lifetime of the control device and is probably better.

### EXAMPLE 4

This example presents selected experimental results from the electrical testing of device o5789. Device o5789 is an embodiment in accordance with the instant invention that includes a dual layer structure having a heterogeneous layer and a homogeneous layer. The layer in contact with the lower electrode is a 200 Å thick homogeneous layer of Ge₁₈Sb₃₇Te₄₅. The layer in contact with the upper electrode is a 550 Å thick heterogeneous layer that included Ge₂Sb₂Te₅ as the operational component and 8% SiO₂ as a promoter component. The I-V (Current-Voltage), R-I (Resistance-Current) and cycle life characteristics of device o5789 over multiple cycles were obtained as described in EXAMPLE 2 hereinabove.

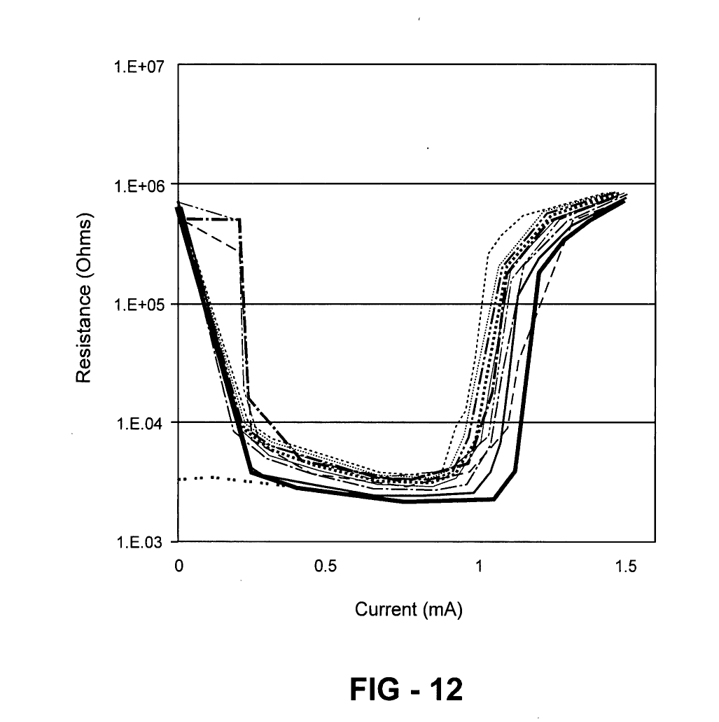

FIG. 12 depicts the R-I characteristics for electronic device o5789 over several cycles of operation. The first cycle of operation is depicted as a series of data points denoted with diamond symbols that begins with the virgin state of the as-fabricated device and extends until the device reached its first reset state. The data point for the device in its virgin state is located at zero current and a resistance of approximately 3.2 kΩ in FIG. 12. As the amplitude of the voltage pulses was increased, the current passing through the device increased. The device resistance remained generally near the virgin resistance until a current of approximately 1.2 mA passed through the device. At this point, the resistance of the device increased substantially and the device was transformed to its reset state. The second cycle of operation began with the device in the reset state obtained upon conclusion of the first cycle of operation. A second series of voltage pulses of increasing amplitude was applied and the resistance and current of the device were measured to produce a second trace of the R-I plot. The resistance of the initial state of the second cycle of operation was close to 1 MΩ. During the second cycle of operation, the device set to a low resistance state at a current of approximately 0.3 mA and reset again beginning at a current of about 1 mA. The cycling process was continued and data traces for several cycles are shown in FIG. 12.

The R-I data for device o5789 indicate that the device required little or no formation. Little variation in the set state resistance and reset state resistance of the device were observed after the first few cycles of operation. Inclusion of a promoter component in a layer of the active region had no significant deleterious effect on the advantageous formation properties observed for the control device in EXAMPLE 2. The R-I data for device o5789 also indicate that the device had a reset current of approximately 1.3 mA, a current that is more than 10% below the reset current of the control device. The results thus indicate that inclusion of a promoter component within a layer of a dual layer device provides the beneficial effect of lowering the reset current of the device relative to the control device. A lower set current was also observed, while a large contrast between the reset resistance and set resistance was maintained upon inclusion of the promoter component.

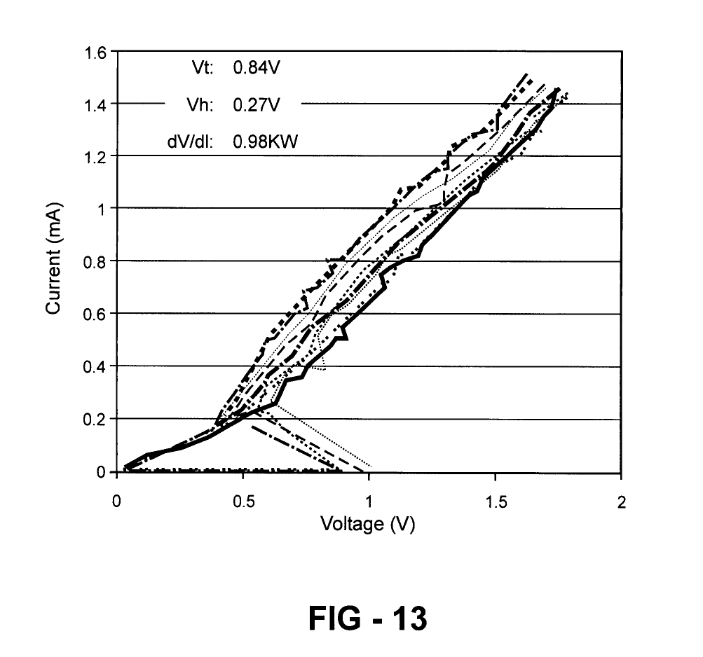

The I-V characteristics of the device o5789 are shown in FIG. 13. I-V traces over several cycles of operation are shown. The I-V trace for the first cycle of operation began with the virgin state and is depicted by the monotonically increasing diamond symbols extending from the origin of the plot and continuing to a voltage of about 1.7 V. No switching was observed for the first cycle of operation. Subsequent cycles of operation demonstrated switching. The I-V characteristics of device o5789 showed little variation after the first few cycles of operation. The I-V data indicated that the threshold voltage of device o5789 was about 0.8 V and that the resistance in the conductive state was about 900-1000Ω. The I-V characteristics of device o5789 were similar to those observed for the control device.

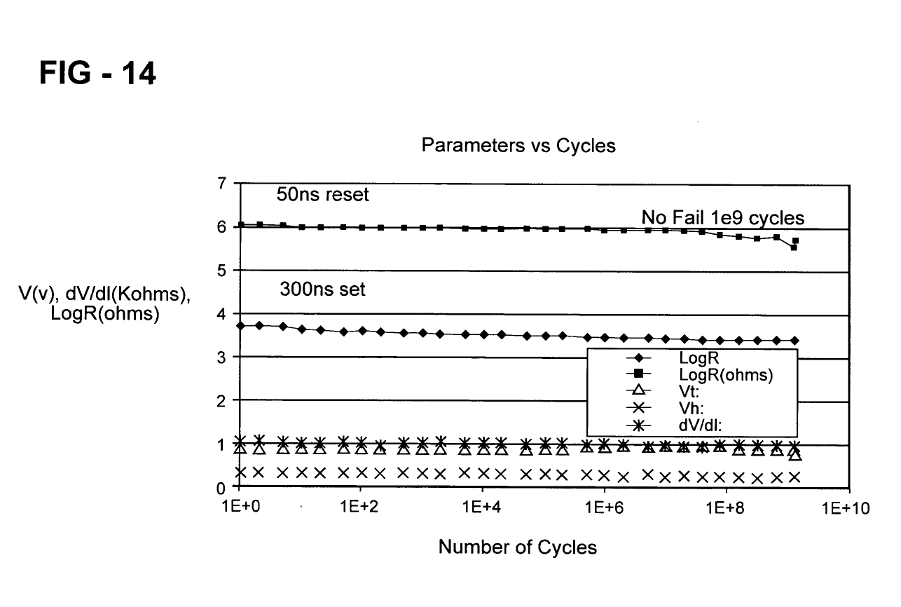

FIG. 14 shows the variation in several performance characteristics of device o5789 over multiple operating cycles. Each operating cycle included a 300 ns set pulse and a 50 ns reset pulse. For each cycle, the set resistance, reset resistance, threshold voltage, holding voltage, and resistance in the conductive branch (dynamic state resistance) of the I-V curve were measured. The results are summarized in FIG. 14. The upper two traces show the variation of reset resistance and set resistance upon cycling. The reset resistance remained stable at approximately 1 MΩ for over 10⁹ operating cycles, at which point the experiment was terminated and no failure of the device had occurred. The set resistance remained stable at a value of below 10 kΩ over the same number of cycles. The lower three traces of FIG. 14 show the variation in holding voltage, conductive branch (dynamic state) resistance, and threshold voltage of the device. All three performance characteristics exhibited stable values for the duration of the experiment. The cycle life tests indicate that inclusion of a promoter material within a layer of the active region of a dual layer device does not have a detrimental effect on durability of the device. The lifetime of device o5789 exceeds the lifetime of the control device.

### EXAMPLE 5

This example presents selected experimental results from the electrical testing of device o5791. Device o5791 is an embodiment in accordance with the instant invention that includes a dual layer structure having a heterogeneous layer and a homogeneous layer. The layer in contact with the lower electrode is a 200 Å thick homogeneous layer of Ge₁₈Sb₃₇Te₄₅. The layer in contact with the upper electrode is a 550 Å thick heterogeneous layer that included Ge₂Sb₂Te₅ as the operational component and 10% SiO₂ as a promoter component. The I-V (Current-Voltage), R-I (Resistance-Current) and cycle life characteristics of device o5791 over multiple cycles were obtained as described in EXAMPLE 2 hereinabove.

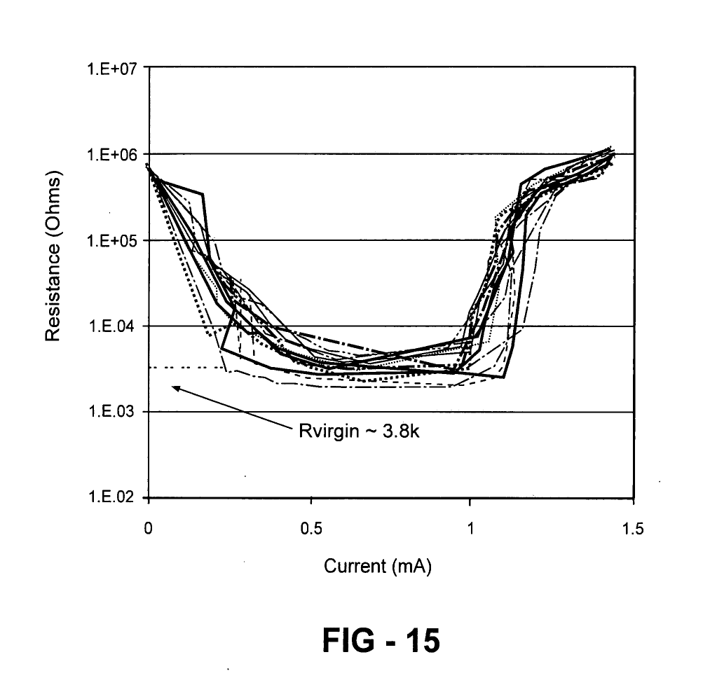

FIG. 15 depicts the R-I characteristics for electronic device o5791 over several cycles of operation. The first cycle of operation is depicted as a series of data points denoted with diamond symbols that begins with the virgin state of the as-fabricated device and extends until the device reached its first reset state. The data point for the device in its virgin state is located at zero current and a resistance of approximately 3.8 kΩ in FIG. 12. As the amplitude of the voltage pulses was increased, the current passing through the device increased. The device resistance remained generally near the virgin resistance until a current of approximately 1.1 mA passed through the device. At this point, the resistance of the device increased substantially and the device was transformed to its reset state. The second cycle of operation began with the device in the reset state obtained upon conclusion of the first cycle of operation. A second series of voltage pulses of increasing amplitude was applied and the resistance and current of the device were measured to produce a second trace of the R-I plot. The resistance of the initial state of the second cycle of operation was close to 1 MΩ. During the second cycle of operation, the device set to a low resistance state at a current of approximately 0.3 mA and reset again beginning at a current of about 1 mA. The cycling process was continued and data traces for several cycles are shown in FIG. 15.

The R-I data for device o5791 indicate that the device required little or no formation. Little variation in the set state resistance and reset state resistance of the device were observed after the first few cycles of operation. Inclusion of a promoter component in a layer of the active region had no significant deleterious effect on the advantageous formation properties observed for the control device in EXAMPLE 2. The R-I data for device o5791 also indicate that the device had a reset current of approximately 1.2 mA, a current that is 20% below the reset current of the control device. The results thus indicate that inclusion of a promoter component within a layer of a dual layer device provides the beneficial effect of lowering the reset current of the device relative to the control device. A lower set current was also observed, while a large contrast between the reset resistance and set resistance was maintained upon inclusion of the promoter component.

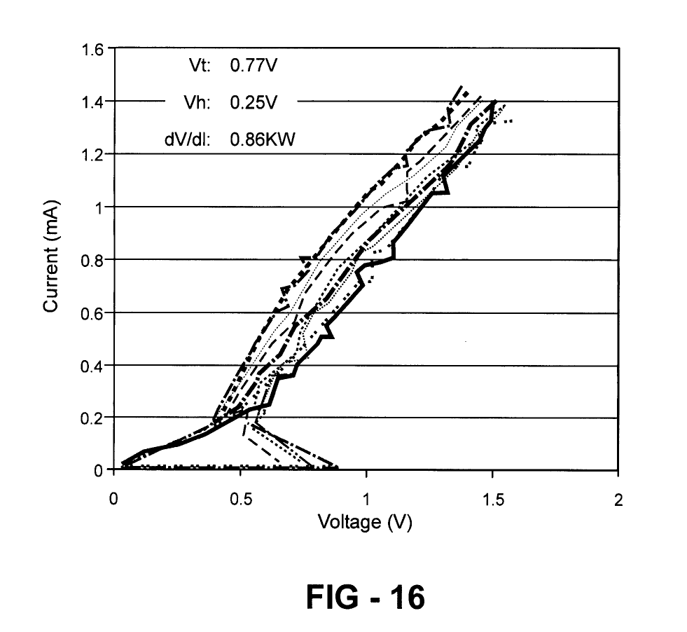

The I-V characteristics of the device o5791 are shown in FIG. 16. I-V traces over several cycles of operation are shown. The I-V trace for the first cycle of operation began with the virgin state and is depicted by the monotonically increasing diamond symbols extending from the origin of the plot and continuing to a voltage of about 1.5 V. No switching was observed for the first cycle of operation. Subsequent cycles of operation demonstrated switching. The I-V characteristics of device o5791 showed little variation after the first few cycles of operation. The I-V data indicated that the threshold voltage of device o5791 was about 0.8 V and that the resistance in the conductive state was about 900Ω. The I-V characteristics of device o5791 were similar to those observed for the control device.

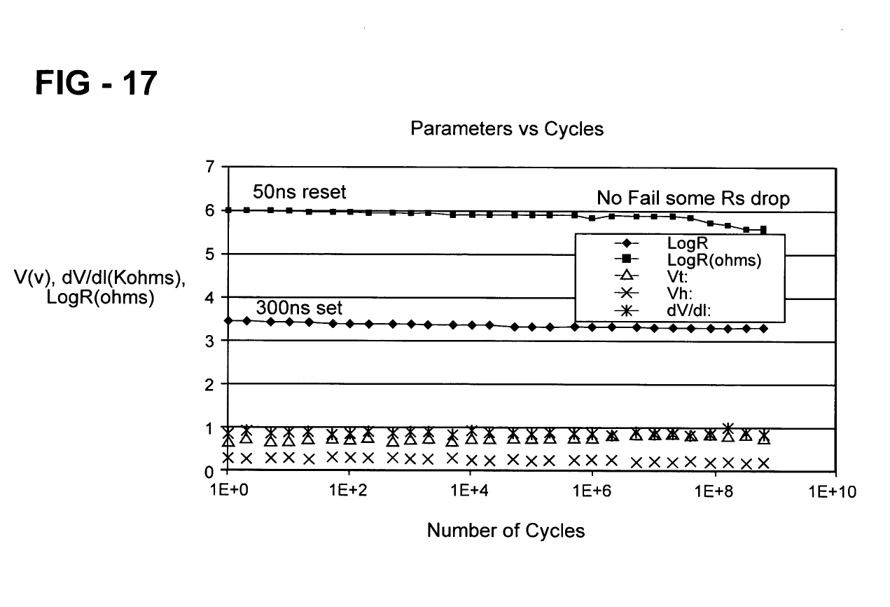

FIG. 17 shows the variation in several performance characteristics of device o5791 over multiple operating cycles. Each operating cycle included a 300 ns set pulse and a 50 ns reset pulse. For each cycle, the set resistance, reset resistance, threshold voltage, holding voltage, and resistance in the conductive branch (dynamic state resistance) of the I-V curve were measured. The results are summarized in FIG. 17. The upper two traces show the variation of reset resistance and set resistance upon cycling. The reset resistance remained stable at close to 1 MΩ for over 10⁹ operating cycles, with a slight decline in the latter stages of the experiment. No failure of the device, however, was observed before terminating the experiment. The set resistance remained stable at a value of below 10 kΩ over the same number of cycles. The lower three traces of FIG. 17 show the variation in holding voltage, conductive branch (dynamic state) resistance, and threshold voltage of the device. All three performance characteristics exhibited stable values for the duration of the experiment. The cycle life tests indicate that inclusion of a promoter material within a layer of the active region of a dual layer device does not have a detrimental effect on durability of the device. The lifetime of device o5791 exceeds the lifetime of the control device.

### EXAMPLE 6

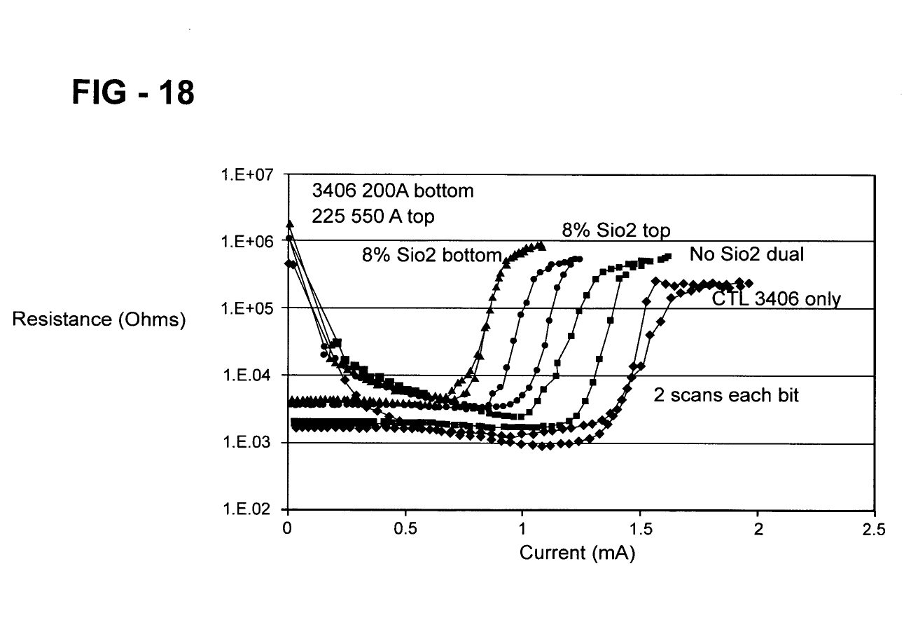

Referring to FIG. 18, a direct comparison of the R-I characteristics of selected devices in accordance with the instant invention and the control device (device o5785) is presented. The R-I response for each device was obtained as described in EXAMPLE 2 hereinabove. The R-I response of devices o5787 and o5789 are compared with the R-I response of the control device and a single layer device in FIG. 18. The single layer device (device o5783) includes a 750 Å homogeneous layer of Ge₁₈Sb₃₇Te₄₅. The R-I trace from the virgin state and an R-I trace for the stabilized state for each device is shown in FIG. 18. The R-I trace from the virgin state for each device begins at the virgin resistance (which is between 1 kΩ and 10 kΩ for each device) and extends to the first reset state. The R-I trace for the stabilized state of each device begins at the stabilized reset resistance, continues through the set resistance, and extends to the reset state. The R-I traces for devices o5787, o5789, control device, and single layer device are depicted using triangle symbols (▴), circle symbols (●), square symbols (▪), and diamond symbols (♦); respectively in FIG. 18. The four traces that begin at a resistance of less than 10 kΩ at zero current are the traces from the virgin state of the devices and the four traces that begin at a resistance of above than 100 kΩ at zero current are the traces of the stabilized devices beginning from the reset state.

The two traces that extend to the highest current were obtained from the single layer device. The alloy Ge₁₈Sb₃₇Te₄₅ has the desirable property of requiring little or no formation. The device in its virgin state is essentially ready for practical operation with no need for conditioning. This characteristic is reflected by the similar appearance of the R-I traces of the virgin state and stabilized state of the single layer device. The drawback of the single layer device, however, is the relatively higher reset current and lower Rᵣₑₛₑₜ.

The dual layer control device o5785 includes a homogeneous layer of Ge₁₈Sb₃₇Te₄₅ and a homogeneous layer of Ge₂2Sb₂Te₅. The two traces for this device indicate a reduction in reset current relative to the single layer device, but a greater disparity between the R-I traces originating from the virgin state and stabilized reset state of the device. This disparity indicates a need to condition the as-processed virgin state device through a series of forming cycles before the device is ready for operation by the end-user. Such conditioning is undesirable because it adds time and expense to the manufacturing process. (As discussed in the '913 application, however, the need for forming the dual layer control device is less than the need for forming a single layer Ge₂Sb₂Te₅ device.)

Device o5789 includes a homogenous layer of Ge₁₈Sb₃₇Te₄₅ in contact with the lower electrode and a heterogeneous layer of Ge₂Sb₂Te₅ and SiO₂ in contact with the upper electrode. Inclusion of the promoter SiO₂ leads to a decrease in reset current relative to the dual layer control device lacking a promoter and at the same time, reduces the need for conditioning the device. The disparity between the R-I traces of the virgin state and stabilized reset state of device o5789 is less than that observed for control device o5785.

Device o5787 includes a heterogeneous layer of Ge₁₈Sb₃₇Te₄₅ and SiO₂ in contact with the lower electrode and a homogenous layer of Ge₂Sb₂Te₅ in contact with the upper electrode. Inclusion of the promoter SiO₂ leads to a decrease in reset current relative to the dual layer control device lacking a promoter and at the same time, reduces the need for conditioning the device. The disparity between the R-I traces of the virgin state and stabilized reset state of device o5787 is less than that observed for control device o5785. The disparity observed for device o5787 is comparable to that observed for single layer device o5783. The R-I characteristics of device o5787 illustrate that inclusion of a promoter material in the active region of the device provides the benefit of a lower reset current, while essentially eliminating the need to form the device.

Those skilled in the art will appreciate that the methods and designs described above have additional applications and that the relevant applications are not limited to those specifically recited above. Also, the present invention may be embodied in other specific forms without departing from the essential characteristics as described herein. The embodiments described above are to be considered in all respects as illustrative only and not restrictive in any manner.

We claim:

1. An electronic device comprising:
a first terminal;
a second terminal;
an active region in electrical communication with said first and second terminals, said active region including a first layer and a second layer, said first layer being a heterogeneous layer.

2. The electronic device of claim 1, wherein said first layer comprises a first component and a second component.

3. The electronic device of claim 2, wherein said first component comprises a phase-change material.

4. The electronic device of claim 2, wherein said first component comprises a chalcogenide material.

5. The electronic device of claim 4, wherein said chalcogenide material comprises Ge.

6. The electronic device of claim 5, wherein said chalcogenide material further comprises Sb and Te.

7. The electronic device of claim 5, wherein the atomic concentration of Ge in said chalcogenide material is less than 22%.

8. The electronic device of claim 7, wherein the atomic concentration of Ge is between 11% and 18%.

9. The electronic device of claim 4, wherein said second component is a non-chalcogenide material.

10. The electronic device of claim 4, wherein said second component is an oxide

11. The electronic device of claim 10, wherein said oxide comprises silicon.

12. The electronic device of claim 4, wherein said second component is a nitride or carbide.

13. The electronic device of claim 4, wherein the volume fraction of said second component in said first layer is less than 20%.

14. The electronic device of claim 13, where the volume fraction of said second component in said first layer is between 3% and 10%.

15. The electronic device of claim 13, where the volume fraction of said second component in said first layer is between 5% and 8%.

16. The electronic device of claim 4, wherein said second layer comprises a chalcogenide material.

17. The electronic device of claim 16, wherein said second layer comprises Ge.

18. The electronic device of claim 17, wherein the atomic percentage of Ge in said second layer is greater than or equal to 22%.

19. The electronic device of claim 17, wherein said second layer further comprises Sb and Te.

20. The electronic device of claim 4, wherein said second layer is a heterogeneous layer comprising a first component and a second component.

21. The electronic device of claim 20, wherein said first component of said second layer comprises a chalcogenide material and said second component of said second layer comprises a non-chalcogenide material.

22. The electronic device of claim 1, wherein said second layer comprises a chalcogenide material.

23. The electronic device of claim 1, wherein said device has a reset state having a reset resistance and a set state having a set resistance, said reset resistance being greater than set resistance by a factor of at least 10.

24. The electronic device of claim 23, wherein the reset current of said device is less than or equal to 1.3 mA.

25. The electronic device of claim 1, wherein said active region further includes a third layer, said third layer being disposed between said first layer and said second layer.
